(19) United States
(12) Patent Application Publication
(10) Pub. No.: US 2026/0308401 A1
(43) Pub. Date: Oct. 8, 2026

(54) Nanoparticle Synthesis on Substrates with Removable Coatings

(71) Applicant: NORTHWESTERN UNIVESITY, Evanston, IL (US)

(72) Inventors: Chad A. Mirkin, Wilmette, IL (US); Peter Thomas Smith, Evanston, IL (US)

(21) Appl. No.: 19/484,684

(22) PCT Filed: May 13, 2024
(86) PCT No.: PCT/US2024/029024

§ 371 Date: Nov. 14, 2025

Related U.S. Application Data
(60) Provisional application No. 63/466,861, filed on May 16, 2023.

(51) Int. Cl. C09D 11/037; B82Y 40/00; C09D 11/102; C09D 11/106; C09D 11/108

(52) U.S. Cl. CPC C09D 11/037; C09D 11/102; C09D 11/106; C09D 11/108; B82Y 40/00

(57) ABSTRACT

A method of forming nanoparticles on a substrate includes coating a substrate with a substrate coating, depositing a precursor ink comprising a polymer and one or more metal ions and/or one or more metal ion precursors onto the substrate coating to form a plurality of polymer nanoreactors comprising the one or more metal ions or the one or more metal ion precursors contained within the polymer nanoreactor, annealing the substrate having the polymer nanoreactors formed on the substrate coating to aggregate the one or more metal ions within the nanoreactor and form nanoparticles within the polymer nanoreactors; and removing the substrate coating thereby resulting in the nanoparticles formed on the substrate.

### CROSS-REFERENCE TO RELATED APPLICATION

The benefit of priority to U.S. Provisional Patent Application No. 63/466,861 filed May 16, 2023, is hereby claimed and the disclosure is incorporated by reference in its entirety.

### FIELD

The disclosure relates to methods of making nanoparticles and nanoparticle libraries on substrates having substrate coatings, and more particularly to methods of making nanoparticles or nanoparticle libraries using polymer-based nanoreactors on substrate coatings to allow for formation of the nanoparticles independent of substrate chemistry.

### BACKGROUND

Materials discovery drives technological advancement yet is slowed by two fundamental challenges: synthesis and characterization. One approach to accelerating discovery is using combinatorial libraries and high-throughput experimentation as demonstrated by research on sustainable catalysis, luminescence, photovoltaics, and more. To prepare such libraries, materials must be precisely patterned on substrates to distinguish differing properties. In doing so, the substrate chemistry and dimensions must be considered since material-substrate interactions are critical for functions such as electron transfer, plasmonics, or catalysis. This is particularly important with nanomaterials where fixed com-positions can have superior properties depending on size. Furthermore, substrate interactions can introduce challenges for patterning nanomaterials such as deposition success, spatial and size fidelity, and poor contact with the substrate that must be addressed. Current approaches to patterning nanomaterials include scanning probe lithography, photolithography, self-assembly, and templating. However, these techniques rely on specific surface preparation or characteristics such as chemical modification, hydrophobicity, and roughness, which limits substrate choice and subsequent applications. Scanning probe lithography offers the highest degree of positional and structural control, but patterning challenges are amplified because the scale of the surface features matches the nanoscale probes used for deposition which must be precisely aligned with the substrate. Thus, it is necessary to remove synthesis-limiting substrate requirements to expand the structural and functional breadth of combinatorial libraries accessible using scanning probe lithography.

The combination of polymer pen lithography (PPL) and scanning probe block copolymer lithography (SPBCL) is a powerful way of making nanoparticle patterns over centimeter substrates with nanometer precision. PPL is a massively parallel technique using up to millions of pyramidal tips to pattern molecules and materials, while SPBCL creates polymer droplets that behave as nanoreactors for particle synthesis with attoliter reaction volumes. Single nanoparticles form in each nanoreactor by loading them with metal salts followed by annealing. This confined synthesis has been used to make metallic or ionic nanoparticles, perovskites, and heterostructured nanoparticles, with controlled composition and size. Patterns consisting of up to 5 billion identical nanomaterials have been synthesized, showing large area parallel synthesis is highly controllable. In addition, megalibraries consisting of gradients of either Au—Cu nanoparticles or mixed halide perovskites have been reported, which has led to the discovery of a new catalyst for single-walled carbon nanotube synthesis and a blue-emitting halide perovskite with recording-breaking photoluminescence intensity, respectively. However, the strict requirements for substrate chemistry (e.g., atomically flat, and typically chemically modified Si-based substrates to ensure clean reactor formation) in addition to low-throughput compositional tuning and screening capabilities, have thus far limited libraries to 100-1000 unique nanomaterials.

### SUMMARY

Methods of the disclosure provide a generalizable approach to megalibrary synthesis, which can be decoupled from the substrate chemical and physical characteristics. Methods of the disclosure use a hydrophobic substrate coating as a universal coating to allow substrate chemistry independent synthesis. Polystyrene thin films, for example, having about 200 nm thickness, can be used in the methods of the disclosure.

It has been observed that the thin films used in the methods of the disclosure minimize surface roughness, are hydrophobic (allowing for uniform reactor synthesis), isolate particle synthesis from the substrate (allowing clean particle formation), and can be thermally removed after patterning to create and take advantage of nanoparticle-substrate interactions. Methods of the disclosure can significantly expand substrate scope, as well as improve patterning yield, allowing one to use increased numbers of pens to create larger and more compositionally and structurally complex libraries.

Methods of the disclosure have been used to successfully generate ~56 million particle libraries consisting of 2,250,000 unique composition/size combinations (Au/Pd/Cu). The megalibrary was screened on a TiO2 substrate with a commercial fluorophore thin film coating to evaluate the catalytic activity of this library and to use it to identify new visible light photocatalysts for organic pollutant degradation. Areas of activity and turnover were determined based upon decreases in fluorescence intensity as a function of time. From this screen, in approximately 1 h, it was possible to identify Au_{0.53}Pd_{0.38}Cu_{0.09}—TiO₂ as a promising pollutant degradation catalyst.

Any inks, metals, and nanoparticle formation methods using nanoreactor and non-reactor-based methods, such as with SBLC and PPL can be used with the methods of the disclosure for forming nanoparticles on the system. The methods of the disclosure can improve such methods, making them more universally applicable to various substrates, including those having roughness or height variation otherwise not conducive to such patterning methods.

It is also contemplated herein that methods of the disclosure can be useful in non-reactor-based patterning methods for patterning on a variety of substrates. Methods of the disclosure can be applied to any metals or groups synthesized using the nonreactor method. It can potentially be used in synthesis methods other than nonreactors, such as drop casting or evaporation to make thin films or multiple particles.

### BRIEF DESCRIPTION OF THE DRAWINGS

FIG. 1 is a schematic illustration of a method in accordance with the disclosure.

FIG. 2A is a dark-field optical microscopy image of square arrays of nanoreactors in 25×25 patterns with 1 μm spacing. Individual pen tips are spaced 50 μm apart.

FIG. 2B is an AFM height image of the nanoreactors patterned on top of a polystyrene thin film by a single pen tip.

FIG. 2C is an SEM image of single Au nanoparticles after annealing at 150-240° C. under H₂ for 18 h where the polystyrene thin film and nanoreactors remain intact.

FIG. 2D is a bright-field optical microscopy image of the square arrays of nanoreactors on polystyrene after this low temperature annealing step.

FIG. 3A to 3F are SEM images of patterns of single Au nanoparticles formed on a range of functional substrates after annealing up to 600° C. to remove the polystyrene thin film and deposit the nanoparticles on the desired substrate. The substrates used are (FIG. 3A) pyrolyzed photoresist film (PPF), (FIG. 3B) doped silicon (Si), (FIG. 3C) polycrystalline tungsten (W), (FIG. 3D) ultra-nanocrystalline diamond film (C), (FIG. 3E) boron nitride film (BN), and (FIG. 3F) silicon carbide film (SiC). Scale bars=1 μm.

FIGS. 4A and 4B. are AFM height images of a bare, polished GC electrode (A) and a polystyrene coated GC electrode (B) with RMS surface roughness of 2.54 nm and 0.24 nm, respectively. Polystyrene thin films have sub nanometer roughness that can compensate for larger height variations in the underlying substrate.

FIG. 4C is an SEM image of patterned single Au nanoparticles formed on GC after polystyrene removal showing that particle formation and patterning is unaffected by large height variations or substrate roughness.

FIG. 4D is an AFM height image of the sol-gel synthesized TiO₂ thin film.

FIG. 4E is a magnified SEM image showing of Au nanoparticles formed on top of the TiO₂ nanoparticles after coating with polystyrene, nanolithography, and thermal annealing.

FIG. 4F is a larger area SEM image of the pattern of larger diameter Au nanoparticles synthesized on TiO₂.

FIG. 5A is a schematic showing four different inks being sprayed at the four corners of a pen array.

FIG. 5B is a graph fitting a Gaussian surface to EDS data acquired from a single spray of a Pt ink. The contours depict the modeled ink intensity gradient from the individual datapoints, which are colored to show the absolute difference between the experimental data and the modeled profile.

FIG. 5C is a graph fitting a Gaussian surface to both EDS and ICP-MS data with the spray profile centered over the top left corner.

FIG. 5D is an image showing four overlaid spray profiles with each centered over the four corners of a 1.5×1.5 cm² pen array. The calculated compositions at the four corners and the center of the array are shown, depicted by black dots.

FIG. 6A is an optical microscope image of a three-component Au—Pd—Cu megalibrary pattern of nanoreactors on a 2×2 cm² polystyrene coated TiO₂ substrate.

FIG. 6B is a graph showing predicted composition gradients of Au—Pd—Cu compositions across the 1.5×1.5 cm² patterned area.

FIG. 6C shows representative SEM images of trimetallic nanoparticles formed on TiO₂ after thermal annealing. Images were acquired in the nine equal sections of the patterned substrate. The bottom images are backscattered electron images due to the reduced Z-contrast between the substrate and Cu- and Pd-rich nanoparticles. Scale bars=1 μm.

FIG. 7A is an optical microscope image of a Au—Pd—Cu megalibrary pattern of nanoreactors on polystyrene coated PPF with each pen tip patterning size gradients.

FIG. 7B is a magnified optical microscope image of the patterned nanoreactors where each pen pattern has a unique metal composition with 25 sizes.

FIG. 7C is a graph showing the dependence of the nanoreactor size on the patterning dwell time and pen velocity.

FIG. 7D is an AFM height image of nanoreactors patterned on polystyrene coated PPF where each row of nanoreactors is patterned using a tip velocity ranging from 50-1250 μm/s and a dwell time ranging from 1.3-0.1 s from top to bottom.

FIG. 7E is an AFM image of a AuₓPd_{y}Cu_{z} nanoparticle size gradient patterned by a single pen tip after thermal annealing to form the arrays of single nanoparticles and remove the nanoreactors and polystyrene.

FIG. 7F is a graph showing the relationship between the nanoparticle height and the nanoreactor volume as estimated from AFM.

FIG. 8A is a schematic for spatially controlled photocatalytic degradation of a rhodamine B thin film by taking advantage of precise positional control of Au nanoparticles via nanolithography on polystyrene coated TiO₂. Loss of fluorescence indicative of dye degradation only occurs where Au is patterned on the TiO₂ because of the required synergistic effects under visible light.

FIG. 8B is a fluorescence microscopy image of a rhodamine B thin film on top of a pattern of Au nanoparticles on TiO₂ after irradiation with visible light showing the spatially selective photocatalytic dye degradation reaction over the Au nanoparticle cocatalyst patterns.

FIG. 9A is a fluorescence microscopy image of a rhodamine B coated Au—Pd—Cu megalibrary after 30 min of visible light irradiation, demonstrating ultrahigh throughput megalibrary screening of visible light photocatalytic degradation of rhodamine B as a model organic pollutant. Scale bar=5 mm.

FIGS. 9B to 9E are magnified images of select regions of the megalibrary demonstrating the differences in fluorescence intensity that correlate with differences in relative catalytic activity and depend on catalyst composition. Scale bars=100 μm.

FIG. 9F shows STEM-EDS mapping of a Au_{0.53} Pd_{0.38}Cu_{0.09} nanoparticle identified as a high-performance trimetallic photocatalyst re-synthesized by DPN/SPBCL. Scale bar=10 nm.

FIGS. 10A and B are images of nanoreactors patterned on unmodified glassy carbon electrode substrates. Poor coverage over large areas was observed due to many pens not being in contact with the uneven surface over centimeter-scale (A), and irregular deposition was observed for pens that were in contact with the substrate due to surface roughness at the nanoscale (B).

FIGS. 11A and 11B are AFM height images of (A) PPF and (B) Si substrates. Roughness measurements of R_{q} were calculated to be 0.24 nm for PPF and 0.09 nm for Si.

FIG. 12A is a thermogravimetric analysis of a polystyrene with an Mₙ of 10,000 and a nanoreactor block copolymer PEO-b-P2VP. The analysis was performed under N₂ at a heating rate of 10° C./min.

FIG. 12B is a schematic of the polystyrene and the PEO-b-P2VP chemical structures.

FIGS. 13A to 131 are SEM images of Au nanoparticles formed during optimization of the polystyrene coating on PPF substrates. The polystyrene Mₙ, the concentration in toluene, and the spin coating speed were varied to identify the film that gave the best yield of single Au nanoparticles in each nanoreactor while maintaining the nanoparticle positioning defined by the PPL patterning and minimizing carbon residue from polystyrene removal. The optimal parameters identified were a polystyrene Mₙ of 10,000 with a concentration of 5% w/v in toluene and a spin coating speed of 2,500 rpm.

FIG. 14 is a graph showing representative height profile measured by profilometry of a polystyrene thin film coating a PPF substrate, showing a polystyrene thickness of 179±7 nm. The polystyrene thin film was fabricated using the optimized protocol, and a scratch was made with a razor blade for thickness analysis.

FIG. 15A is an AFM height image of nanoreactors patterned on polystyrene films.

FIG. 15B is a plot of the height profile showing a uniform pattern of nanoreactors.

FIGS. 16A and 16B are dark-field optical microscopy images showing an entire pattern of nanoreactors formed over a 2.25 cm² polystyrene coated PPF substrate (A), and a magnified image showing the individual nanoreactors (B).

FIG. 17A is a thermogravimetric analysis of alternative polymers and molecules for use as substrate coatings for additional control of hydrophobicity and thermal treatment.

FIG. 17B are schematic of the chemical structure of the polymers tested in FIG. 17A.

FIGS. 18A to 18D are SEM images of Au nanoparticle patterns formed after patterning on PPF substrates coated with alternative polymer and molecular coatings followed by thermal annealing.

FIGS. 19A to 19H are dark-field optical microscopy images of nanoreactor patterns deposited on polystyrene films coating PPF, diamond, silicon, boron nitride, silicon carbide, tungsten, glassy carbon, and titania substrates. Each square array that is visible is a 25×25 pattern of nanoreactor droplets spaced 1 μm apart.

FIGS. 20A to 20F are larger area SEM images showing Au nanoparticle pattern formation on substrates with varied physical structuring.

FIG. 21 shows water contact angle measurement on a polystyrene coated PPF substrate.

FIG. 22 shows water contact angle measurements on the investigated substrates as received and after coating with polystyrene, patterning, nanoparticle formation, and polystyrene removal at elevated temperature, indicating only minor changes in substrate hydrophobicity.

FIG. 23 is a grazing incidence X-ray diffraction of synthesized TiO₂ thin films on silicon substrates showing an anatase structure. The spectra were also collected after the TiO₂ substrate was subjected to thermal annealing under H₂ for nanoparticle synthesis as well as subsequent thermal annealing in air for 2 h to mimic the photocatalyst preparation protocol. The anatase structure appears unchanged during each step. Multiple peaks between 50-60° are observed due to the silicon substrate in accordance with literature.

FIG. 24 shows a water contact angle measurements of TiO₂ film substrates as synthesized, after thermal annealing under H₂, and after subsequent thermal annealing under air and washing with isopropanol.

FIG. 25 is a plot of the number of Au nanoparticles formed within individual nanoreactors patterned on polystyrene coated substrates. The analysis was performed using many SEM images.

FIG. 26 shows SEM and AFM images of nanoparticle patterns synthesized by SPBCL and PPL on removable polystyrene coated substrates demonstrating a broad scope of compatible metal element inks.

FIG. 27 is an image of the spray gun setup above a positioned pen array with a 3D-printed mask so only the central 1.5×1.5 cm² area of pens are exposed to the sprayed ink. The spray gun nozzle is positioned 11.5 cm above the pen array and is centered over the top-left corner of the pen area.

FIG. 28A is an optical image of a 5 μL spray of methylene blue.

FIG. 28B is an image showing an overlay of average color intensity datapoints with a Gaussian distribution surface plot.

FIG. 28C is 28D visualization of the modeled Gaussian distribution.

FIG. 29 is a representative EDS spectrum of a Pt ink sprayed onto a carbon paper substrate. Additional peaks for F from a hydrophobic treatment of the commercial carbon paper and minor S contamination are observed.

FIGS. 30A-30D shows overlay of ICP-MS metal concentration datapoints with Gaussian distribution surface plots.

FIGS. 31A to 31D shows plots depicting the dependence of the nanoreactor and nanoparticle dimensions on the patterning parameters.

FIG. 32A is an SEM image of size gradients of Au nanoparticles.

FIG. 32B is an SEM image of size gradients of AuPdCu nanoparticles.

FIG. 33 Is an AFM height image of a Au nanoparticle size gradient with nanoparticle heights ranging from approximately 5 nm to 25 nm. The patterning parameters used variation of the dwell time from 1.2 to 0.0 s and pen velocity from 100 to 1300 μm/s.

FIG. 34 is graph showing an absorption spectrum of the TiO₂ thin film synthesized on a transparent quartz substrate.

FIGS. 35A and 35B shows fluorescence microscopy images of (A) control photocatalysis experiments using bare TiO₂ substrates or (B) Au nanoparticles patterned on silicon. The samples were prepared and subjected to the same visible light photocatalysis conditions as the Au nanoparticle patterns on TiO₂. No significant change in fluorescence is observed indicating the importance of the combined Au nanoparticle and TiO₂ substrate for effective rhodamine B degradation.

FIG. 36A is a) plot of the coordinates identified as the positions of lowest fluorescence intensity from a series of Au—Pd—Cu megalibrary replicates.

FIG. 36B is a graph showing identification of the centroid coordinates for the two clusters observed to identify the compositions of the highest performing catalysts.

FIG. 36C shows representative fluorescence microscopy images of megalibrary screening of photocatalytic rhodamine B degradation. Defects due to incomplete patterning or dust and pinholes from spin coating error were accounted for when identifying regions of lowest fluorescence intensity. Scale bars=3 mm.

FIG. 37A is an EDS spectrum of a Au_{0.53} Pd_{0.38}Cu_{0.09} nanoparticle synthesized by DPN/SPBCL.

FIG. 37B shows dark-field and bright-field STEM images of the characterized nanoparticle.

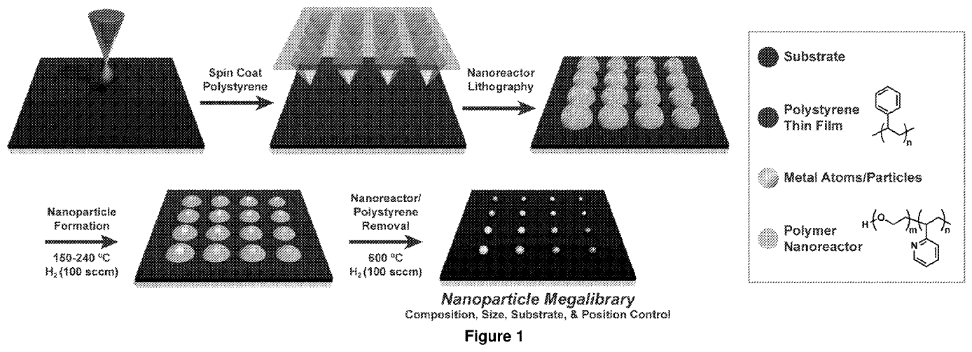

### DETAILED DESCRIPTION

Methods of forming nanoparticle libraries in accordance with the disclosure include coating a substrate with a hydrophobic substrate coating, depositing a precursor ink onto the substrate coating to form polymer nanoreactors having metal ions contained thereon onto the substrate coating, annealing the nanoreactors to aggregate metal ions within the nanoreactor and form nanoparticles and optionally removing the nanoreactors and/or the substrate coating. Methods of the disclosure can advantageously provide a process in which the nanoreactors are insulated from the substrate functional groups and/or negate the effects of surface roughness.

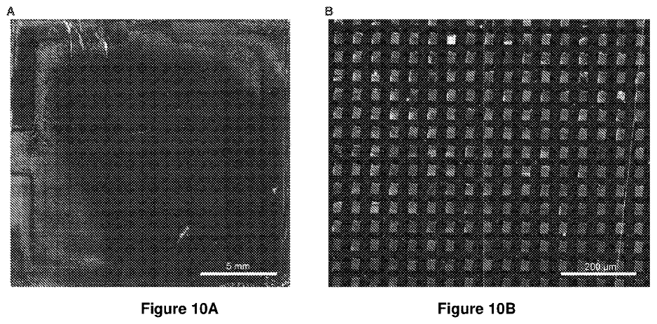

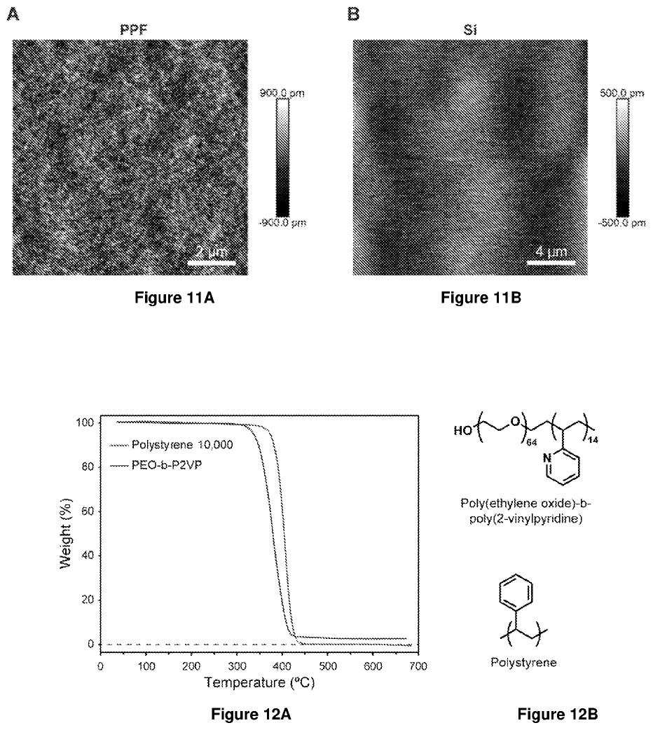

Megalibrary synthesis on conductive or semiconductive substrates for applications in electrochemistry and photochemistry is challenging because of the roughness and surface chemistry containing functional groups or defects that bind metal atoms and particles. For example, the nanoscale roughness of polished glassy carbon (GC) electrodes causes inconsistent nanoreactor deposition due to poor alignment between the pen tips and substrate (FIG. 10). Accordingly, a flatter conductive carbon was developed using pyrolyzed photoresist films (PPF), which are thin carbon coatings on silicon with sub-nanometer surface roughness as measured by atomic force microscopy (AFM) (FIG. 11). However, annealing under H₂ of nanoreactors containing HAuCl₄ did not result in Au nanoparticle formation. Without intending to be bound by theory, it is believed that the coalescence of reduced metal atoms within the nanoreactor is inhibited by strong binding interactions with the carbon substrate. Methods of the disclosure eliminate such interactions, by providing a thin film that insulates the nanoreactors from the functional groups of the underlying substrate.

The substrate coating can be selected such that it provides a flat/uniform film on the substrate and can be removed thermally. For example, the substrate coating can have a surface roughness of 1 nm or less. Substrate coatings for use in the methods of the disclosure can be hydrophobic. For example, the substrate coating can have a water contact angle of greater than 75°. The substrate coatings can be polymer or molecular coatings that decompose at temperatures higher than an annealing temperature for forming the nanoparticles. For example, the coating can be polystyrene, polyethylene, Poly(α-methyl styrene), Poly(2,6-dimethyl-1,4-phenylene oxide), polyolefins, polydienes or poly(pentafluorostyrene). Additional coatings can include, for example, poly(tetrafluoroethylene), poly(vinylidene fluoride), or other fluorinated or non-fluorinated hydrophobic polymers that decompose fully at elevated temperatures. Molecular coatings can include, for example, molecular coatings of rubrene, pyrene, terphenyl, triptycene, hexaphenylbenzene, or coroners. Other coating materials can include high melting/boiling point molecular solids, or solids that sublime

The substrate coating material and properties thereof, such as hydrophobicity and thermal decomposition, can be selected depending on the material to be patterned on the substrate. For example, for nanoreactor-based formation methods, a substrate coating can have a thermal decomposition temperature of about 250° C. to 600° C. Substrate coatings with thermal decomposition temperatures of about 100° C. to 250° C. can be useful for lower temperature materials synthesis and/or thermally sensitive substrates.

The substrate coating can have a thickness, for example, of about 100 nm to about 500 nm.

The substrate coating can be deposited on the substrate using any known methods. For example, spin coating, dip coating, drop casting, vapor deposition, or spray coating the substrate coating onto the substrate can be used.

Various substrates can be used in the methods of the disclosure. For example, the substrate can be or include one or more of glassy carbon, pyrolyzes photoresist, graphene, HOPG, diamond, boron nitride, silicon carbide, tungsten, molybdenum, titanium, and/or titania. Beneficially, methods of the disclosure can be useful in allowing for formation of nanoparticles through nanoreactor synthesis methods and other methods on substrates not otherwise conducive to such formation methods. For example, substrates having height variations of 5 nm or more can be difficult to process using common nanoreactor synthesis-based methods. However, such substrate can be utilized and patterned successfully using the methods of the disclosure. Without intending to be bound by theory, it is believed that the substrate coating can form a fluid film during the annealing step for forming the nanoparticles that compensates for surface roughness in the underlying substrate, thereby providing a more universal surface for deposition of the nanoreactors.

Polystyrene is hydrophobic and stable over a range of temperatures commonly used in forming nanoparticles from polymer nanoreactors. For example, polystyrene is stable over the temperature range of 100° C. to 250° C., which is the common temperature range used for SPBCL and PPL. Polystyrene also depolymerizes at more elevated temperatures and does not rely upon specific surface chemistries for attachment. Referring to FIG. 12, thermogravimetric analysis (TGA) was used to confirm decomposition of polystyrene with a Mₙ of 10,000 g/mol at 404° C. with 100% weight loss. TGA of the nanoreactor poly(ethylene oxide)-b-poly(2-vinylpyridine), PEO-b-P2VP, showed decomposition at 380° C. with 2 wt % residue after heating to 650° C., consistent with observations of carbon residue around nanoparticles synthesized by SPBCL (FIG. 12). Further, the glass transition temperature (T_{g}) of polystyrene is about 90-100° C.,³⁷ so it is believe that the polystyrene can form a fluid film during the annealing step that compensates for surface roughness.

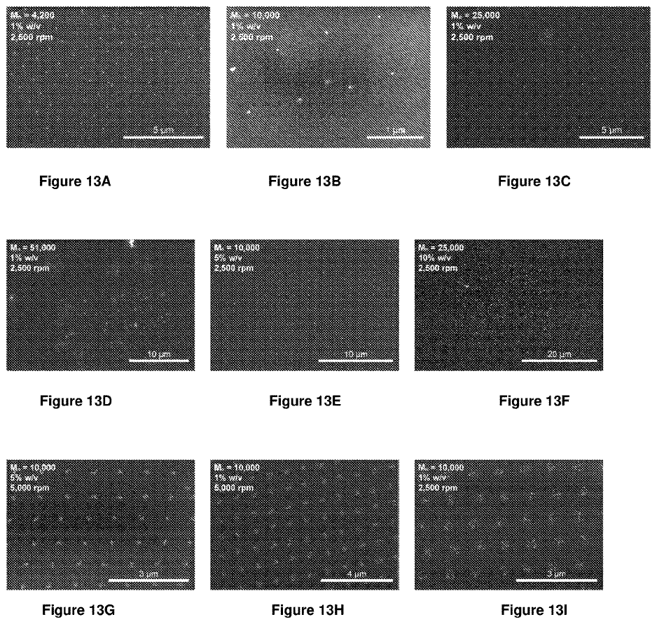

The effects of polystyrene film thickness on patterned Au nanoparticle formation (FIG. 13) was evaluated. PPF substrates were modified with polystyrene films while varying the Mₙ, concentration, or spin coating speed. Nanoreactors of PEO-b-P2VP with HAuCl₄ were patterned and annealed to form Au nanoparticle patterns (240° C.) and remove the polystyrene (600° C.). Parameters that yielded thinner films resulted in multiple Au nanoparticles formed per nanoreactor. With thinner coatings, the nanoreactor may contact the substrate, facilitating atom-substrate interactions that hinder single nanoparticle formation. In contrast, thicker coatings gave predominantly single Au nanoparticles per nanoreactor; however, occasionally the spatial arrangement of nanoparticles became disordered, and residue was observed, indicative of increased mobility of the nanoreactor or nanoparticle and incomplete polystyrene removal. It was identified that a 179±7 nm thick polystyrene thin film using a Mₙ of 10,000 g/mol sufficiently separated nanoreactors from the substrate leading to successful formation of single nanoparticle patterns (FIG. 14).

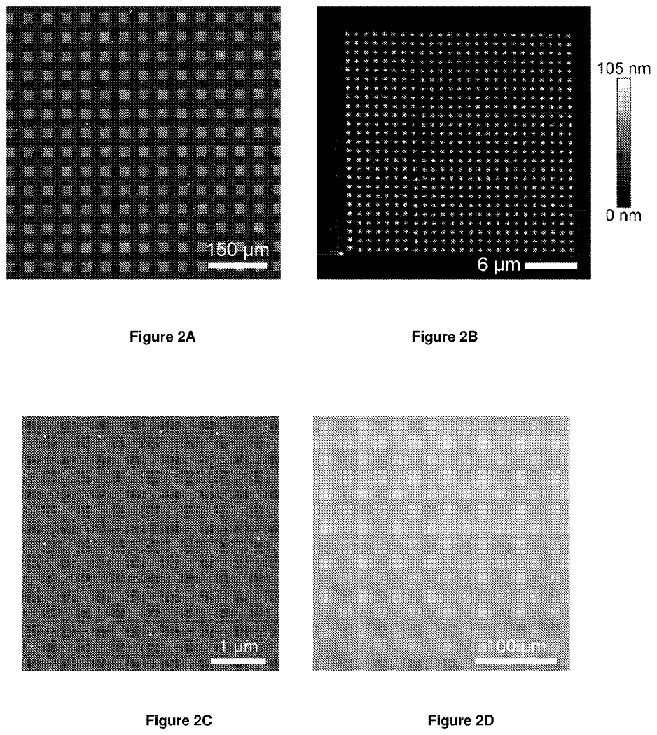

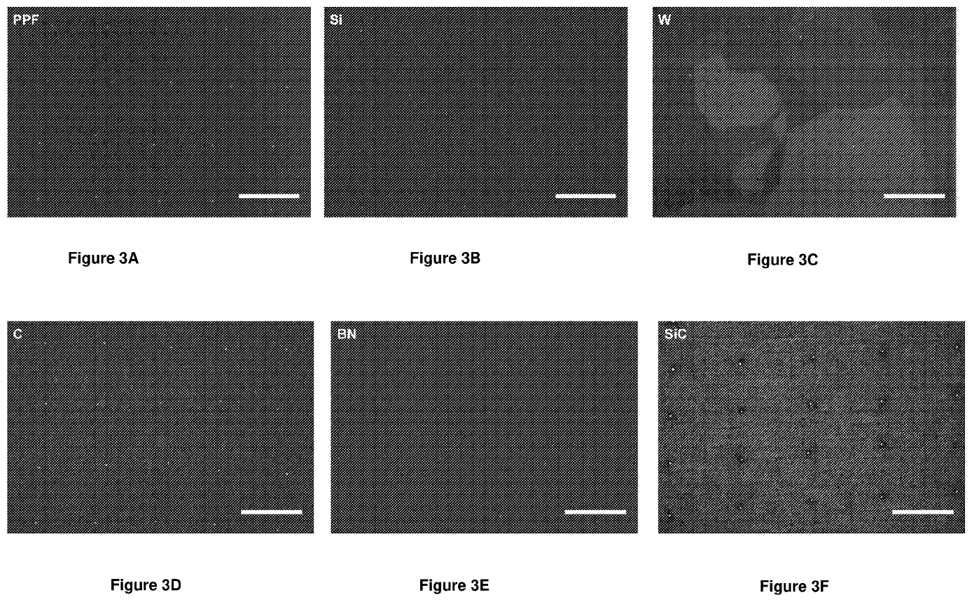

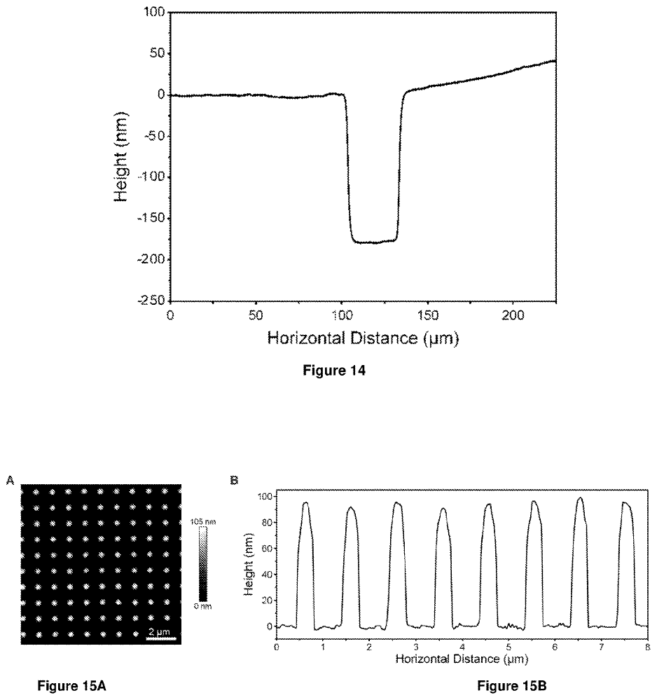

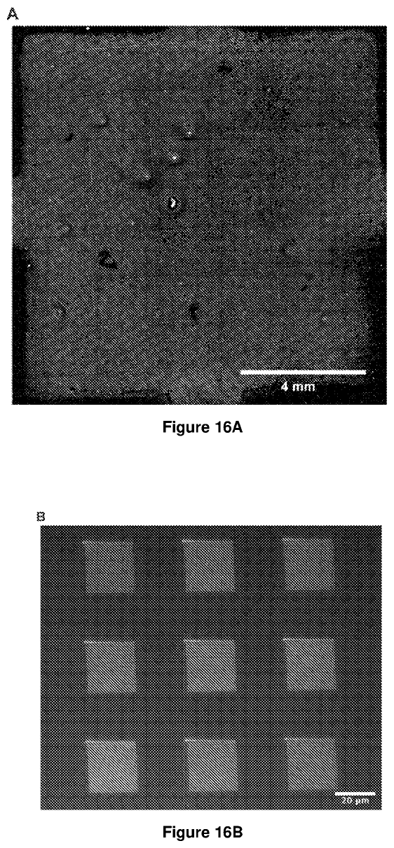

Polystyrene was used as a surface modifier to pattern nanoparticles over large areas by PPL. In a typical experiment, a 1.5×1.5 cm² area is patterned using 90,000 pen tips separated 50 μm apart. The pen array was coated with an aqueous ink of PEO-b-P2VP and metal salt, and each pen was repeatedly touched to the substrate to create a 25×25 pattern of nanoreactors with 1 μm separation. In total, 56,250,000 nanoreactors were patterned within 30 min. FIGS. 2A and 2B show dark-field optical microscopy and AFM height images of a nanoreactor pattern on polystyrene, respectively. The nanoreactors averaged 96.1±2.9 nm high and 434.9±11.0 nm in diameter (FIGS. 15-16). After annealing at 150-240° C. under H₂ for 18 h, scanning electron microscopy (SEM) confirms that single Au nanoparticles were formed while the polystyrene coating remains intact (FIG. 2C). Interestingly, AFM revealed a flat surface without noticeable nanoreactors despite thermal treatment below what is required for nanoreactor removal; however, bright-field optical microscopy clearly showed a square pattern on the polystyrene thin film (FIG. 2D). These patterns match the 25×25 μm² patterns made by each pen, but the individual nanoreactors could not be resolved, possibly due to increased light scattering. This suggests that above the T_{g} of polystyrene and nanoreactor, the two become slightly mobile or miscible, resulting in the entrapment of nanoreactor in polystyrene without loss of spatial fidelity. In the context of thin film optimization, 179±7 nm thick polystyrene coatings were observed to sufficiently encapsulate 96.1±2.9 nm nanoreactors without the nanoreactors contacting the substrate. Further annealing to 600° C. for 6 h fully removed the polystyrene thin film and degraded the nanoreactor polymer to deposit the nanoparticle pattern on the desired substrate (FIG. 3).

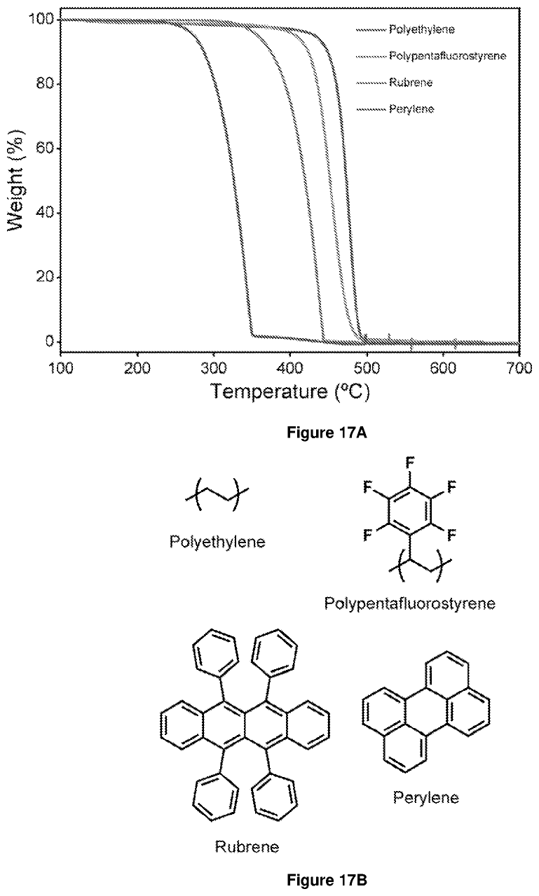

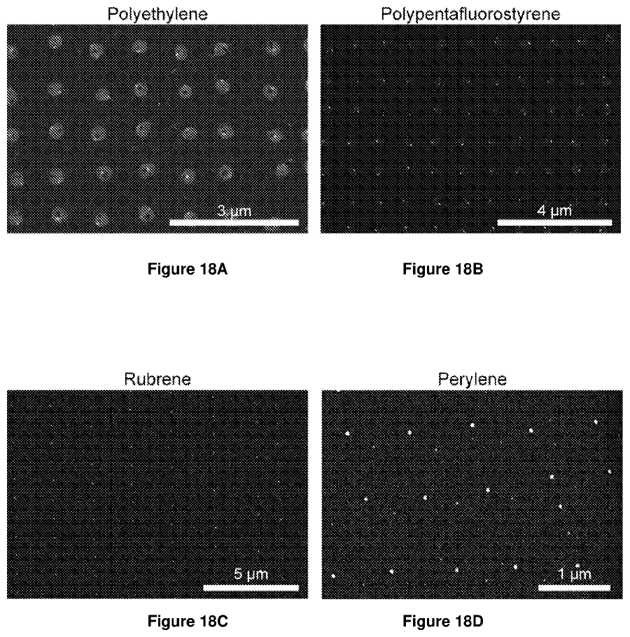

Alternative polymer or molecular films were also explored as universal substrate coatings for SPBCL and PPL. This includes poly(ethylene) and poly(pentafluorostyrene), which decompose at 473 and 452° C., respectively (FIG. 17). Furthermore, the method of the disclosure was also demonstrated as successful when using molecular coatings of rubrene and perylene, chosen for their sublimation behavior. In each case, the substrate coatings were flat and hydrophobic for nanoreactor patterning, and single Au nanoparticles formed after heat treatment up to 600° C. (FIG. 18). Thus, the choice of substrate coating can allow tuning of the surface hydrophobicity or thermal treatment, if needed.

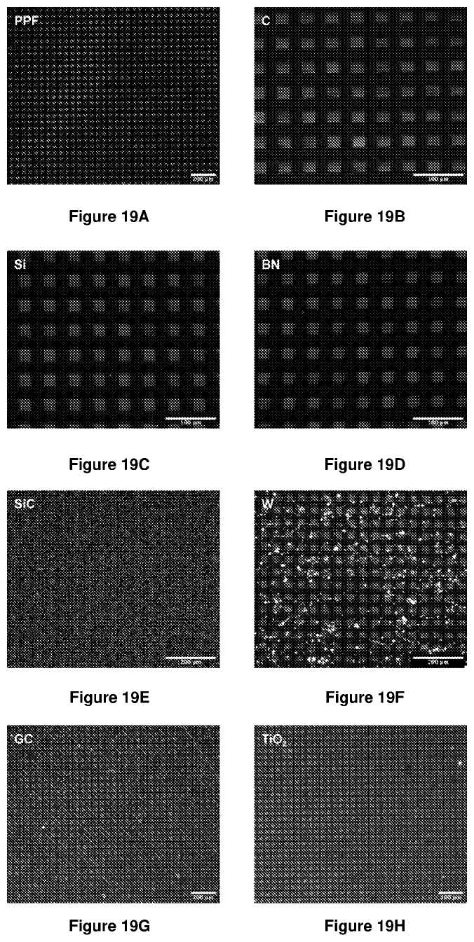

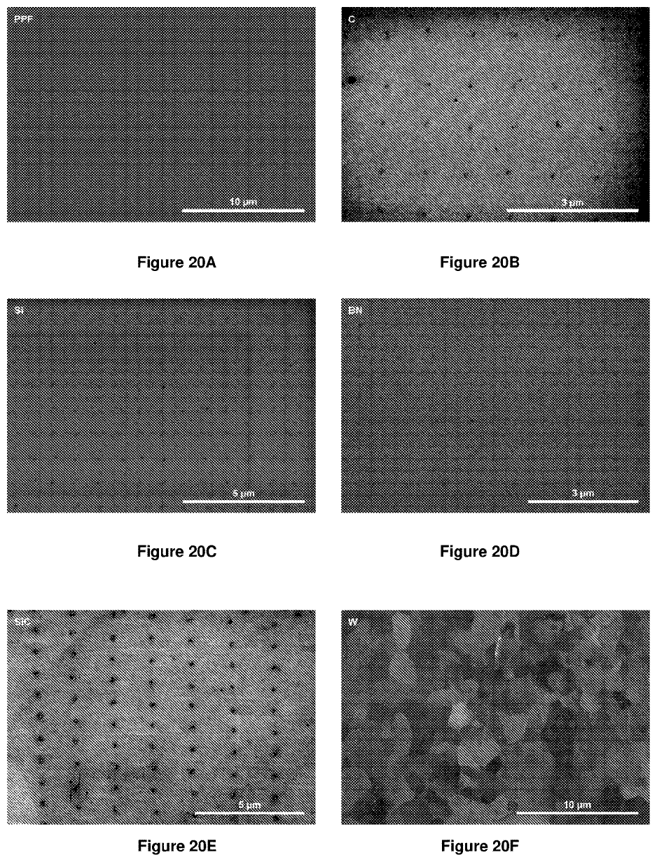

Methods of the disclosure can allow for nanoreactor patterning and nanoparticle synthesis to extend to diverse substrate chemistries. PPF carbon, silicon wafer, polycrystalline tungsten, ultra-nanocrystalline diamond film, amorphous boron nitride film, and silicon carbide film substrates were each coated with polystyrene thin films and patterned with nanoreactors containing HAuCl₄ by PPL. Optical microscopy showed that each of these identically modified substrates could be patterned with nanoreactors using the methods of the disclosure, without having to individually address each substrate's surface chemistry and nanostructuring (FIG. 19), and subsequent thermal treatment yielded patterns of Au nanoparticles (FIG. 3). The selection of substrates spans a range of conductors, semiconductors, and insulators that are valuable for applications in electrocatalysis, photocatalysis, energy storage, photoluminescence, corrosion resistance, and biomedicine. Importantly, while the PPF and silicon substrates were established to be sufficiently flat for use in SPBCL/PPL, patterned Au nanoparticle synthesis was also successful on the amorphous surfaces of vapor-deposited boron nitride or silicon carbide films, the grain boundaries in polycrystalline tungsten, or the nanocrystallinity of diamond films as seen in larger area SEM images (FIG. 20).

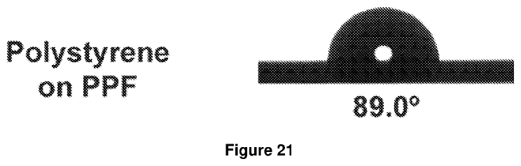

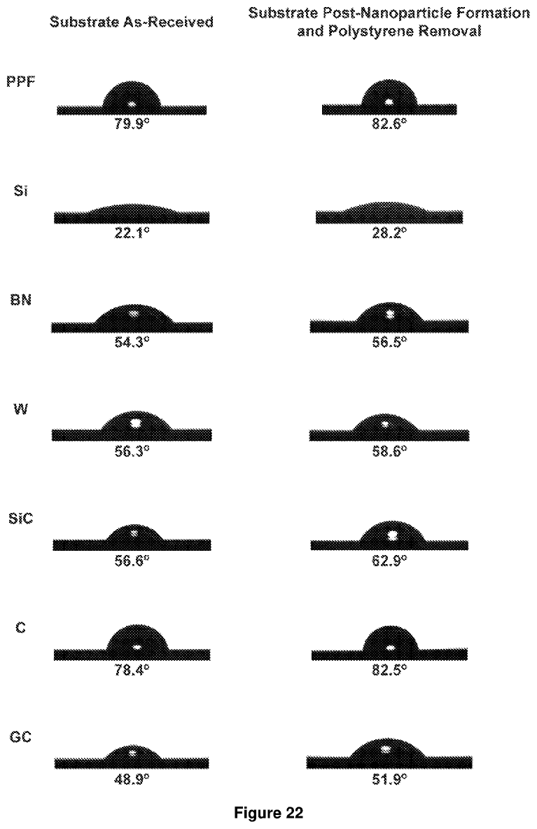

For successful nanolithography, the hydrophobicity of the substrate and the patterned ink must be appropriately matched. With aqueous inks, the substrate must be sufficiently hydrophobic for the deposition of nanoreactors with diameters<1 μm, the size regime required for single nanoparticle formation. This is achieved by treating silicon, silica, or silicon nitride substrates with hexamethyldisilazane, which can be applied to other substrates but is highly sensitive to the surface chemistry, making alternative hydrophobic modification strategies, such as used in the method of the disclosure, advantageous. For example, substrates like PPF, diamond, boron nitride, and silicon carbide require more elaborate approaches for surface modification and may induce irreversible changes. The formation of substrate coatings in accordance with the disclosure was observed to be independent of the surface chemistry and hydrophobicity of the underlying substrate; therefore, it can be applied to differing surfaces while maintaining the hydrophobicity required for nanoreactor patterning. For example, the water contact angle on a polystyrene thin film was measured to be 89.0±1.3°, which is sufficiently hydrophobic for patterning aqueous inks (FIG. 21). Water contact angles were measured on each substrate before and after modifying with polystyrene, patterning, nanoparticle formation, and polystyrene removal. The contact angles of the bare substrates varied from 22° to 80° (FIG. 22), and these values were not significantly affected by the nanoparticle synthesis process. Indeed, the contact angles increased by less than ~5° after these steps, which may be attributed to the presence of Au nanoparticles or trace organic residue from incomplete nanoreactor decomposition. Thus, this strategy of using removable substrate coatings to facilitate patterning and nanoparticle formation can be modular and does not lead to substantial change in the underlying substrate surface wettability.

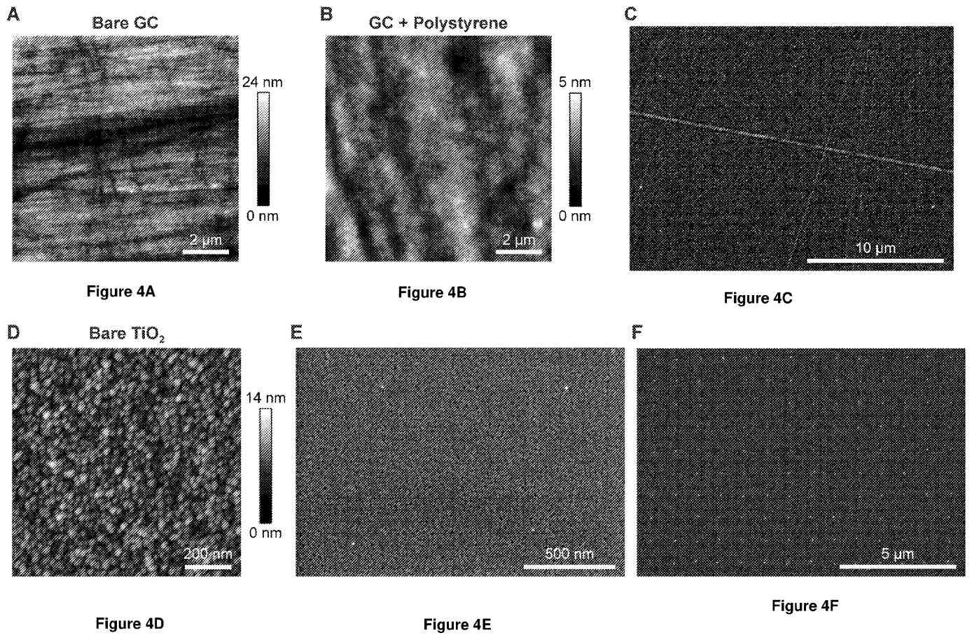

The substrate coatings of the disclosure can also be useful to compensate for the nanoscale roughness on the substrate to facilitate nanoreactor patterning and nanoparticle synthesis as seen in Au nanoparticle patterns synthesized on tungsten, diamond, and silicon carbide substrates that have visible grain boundaries or surface roughness (FIGS. 2, 20). As proof of concept, nanoparticle patterning on GC electrodes that exhibit relatively substantial surface roughness was analyzed. AFM analysis shows a GC surface with a calculated root-mean-square roughness (R_{q}) of 2.54 nm and maximum height variations exceeding 20 nm (FIG. 4A). After coating this GC substrate with polystyrene, the R_{q} decreased 10-fold to 0.24 nm and height variations were less than 5 nm (FIG. 4B). This sub-nanometer roughness is comparable to that of silicon substrates (FIG. 11). Finally, after patterning and thermal annealing, patterns of Au nanoparticles were readily synthesized on the desired GC substrate (FIG. 4C). Even scratch features in the GC formed by mechanical surface polishing did not significantly hinder particle formation.

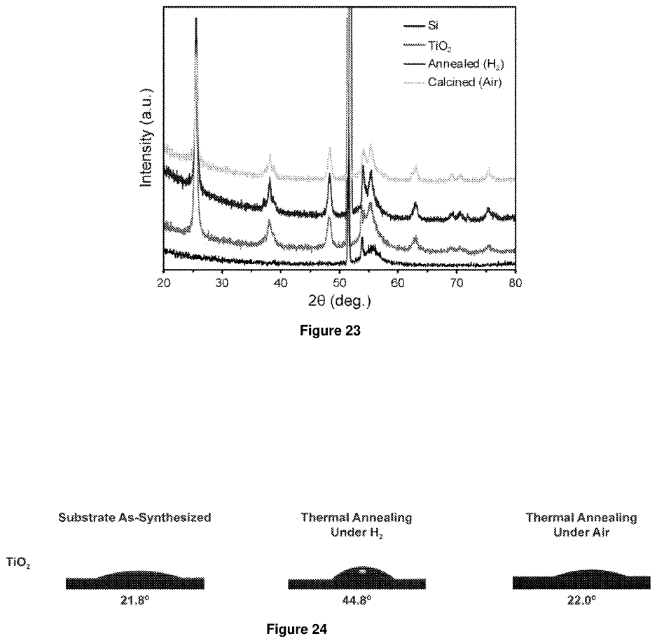

Methods of the disclosure with patterning PEO-b-P2VP nanoreactors and particle synthesis on nanoparticulate surfaces consisting of a thin film of titanium dioxide (TiO₂) nanoparticles on a silicon substrate were evaluated. To evaluate this capability, a 1:4 acetylacetone:ethanol solution of titanium (IV) isopropoxide was spin coated on a silicon wafer and annealed in air at 600° C. for 2 h to form a TiO₂ nanocrystalline thin film. AFM imaging of this thin film showed TiO₂ particles ranging in size from ~10-50 nm uniformly coated the substrate (FIG. 4D). Grazing incidence X-ray diffraction (XRD) reveals an anatase crystal structure, pointing to the potential photocatalytic capabilities of this substrate (FIG. 23). The R_{q} of the TiO₂ film was 2.03 nm, and after coating with polystyrene the R_{q} was reduced to 0.27 nm. This polystyrene coated TiO₂ substrate was patterned with nanoreactors and thermally annealed to successfully synthesize Au nanoparticles. FIG. 4E shows a magnified SEM image of Au nanoparticles on the nanocrystalline TiO₂ with diameters of 13±1 nm estimated by SEM, and FIG. 4F shows a minor portion of a large-area pattern of Au nanoparticles by SEM. To facilitate imaging, the Au nanoparticles in FIG. 4F were synthesized using nanoreactors with an increased metal precursor concentration to yield nanoparticles with diameters of 55±4 nm. Taken together, the polystyrene coating on the TiO₂ nanoparticle film masks the surface roughness allowing for the synthesis of precise patterns of nanoparticle-nanoparticle interfaces between Au and TiO₂. Contact angle measurements of the TiO₂ film before and after patterning and thermal annealing are consistent with a dramatic increase in surface hydrophobicity. This is attributed to partial reduction of the TiO₂ surface rather than a reaction with polystyrene, as similar wettability changes are observed with unmodified TiO₂ substrates (FIG. 24). A final calcination or air plasma treatment step restores the TiO₂ substrate hydrophobicity, and the XRD of the TiO₂ does not show a change from anatase after thermal treatment under H₂ or air (FIG. 23). Overall, the ability to pattern nanoparticles on substrates that have significant height variations or are composed of nanostructured materials greatly expands the substrates of interest for megalibrary-enabled materials discovery.

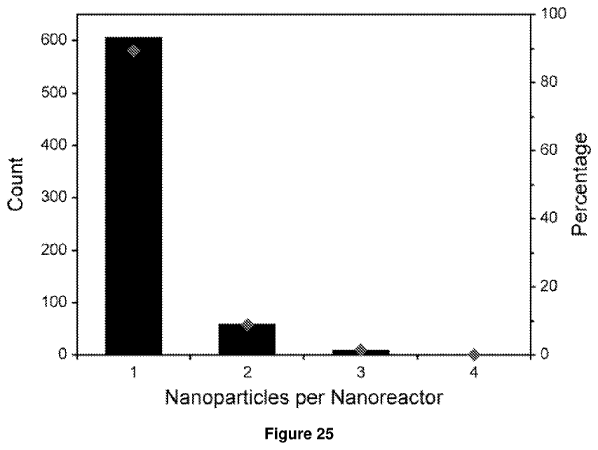

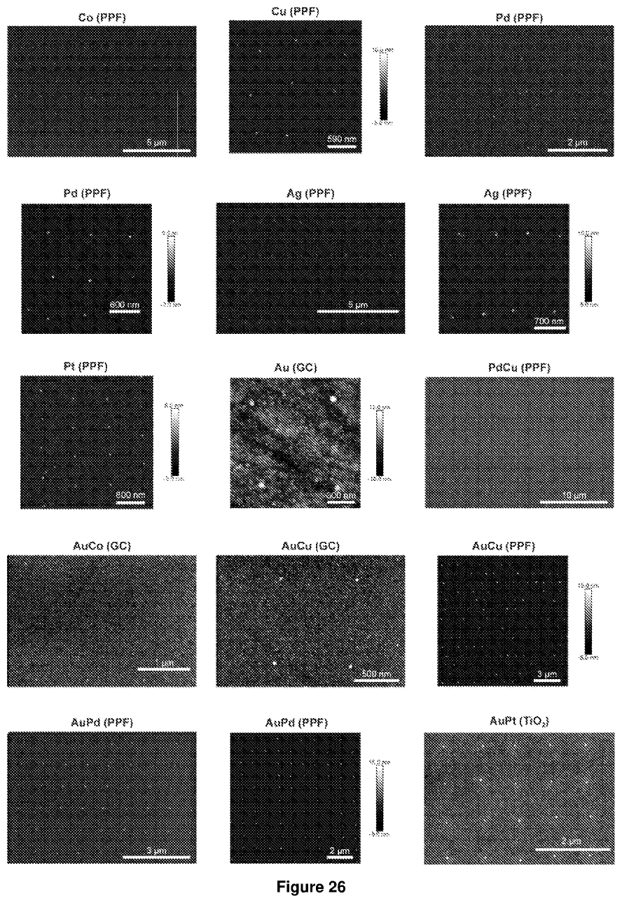

The yield of single Au nanoparticles formed per nanoreactor was calculated across all the substrates identified, resulting in single nanoparticles formed in 90% of patterned nanoreactors as determined by SEM (FIG. 25). Single nanoparticle yield is a unique advantage of SPBCL since it allows deliberate control over nanoparticle size and composition based on the precursor concentration and stoichiometry in the patterned ink, and it can also enforce interface formation between immiscible metals leading to complex heterostructure design. This imparts a level of materials synthetic control that mimics the atomic precision of molecular synthesis. Patterns of nanoreactors containing Co, Cu, Pd, Ag, or Pt precursors were synthesized on polystyrene coated substrates and subjected to thermal annealing and polystyrene removal, demonstrating the capability of the methods of the disclosure for a variety of nanoparticle compositions. Patterns of predominantly single nanoparticles of each of these elements were obtained (FIG. 26). Some residue surrounding the particles, particularly for Co and Ag, is observed and attributed to the more negative standard reduction potentials or decreased mobility relative to Au. Additionally, nanoreactors containing 1:1 PdCu, AuCo, AuCu, AuPd, or AuPt precursors yielded single nanoparticle patterns (FIG. 26). Other nanoparticle compositions that can be formed using the methods of the disclosure and the polystyrene thin films can include, for example, Ir, Ru, IrRu, RuMn, RuCoMnCr. Other compositions and combinations of metals identified herein are also contemplated herein. Thus, the well-established SPBCL protocols do not require modification for patterning on new substrates if these substrates are first coated with polystyrene.

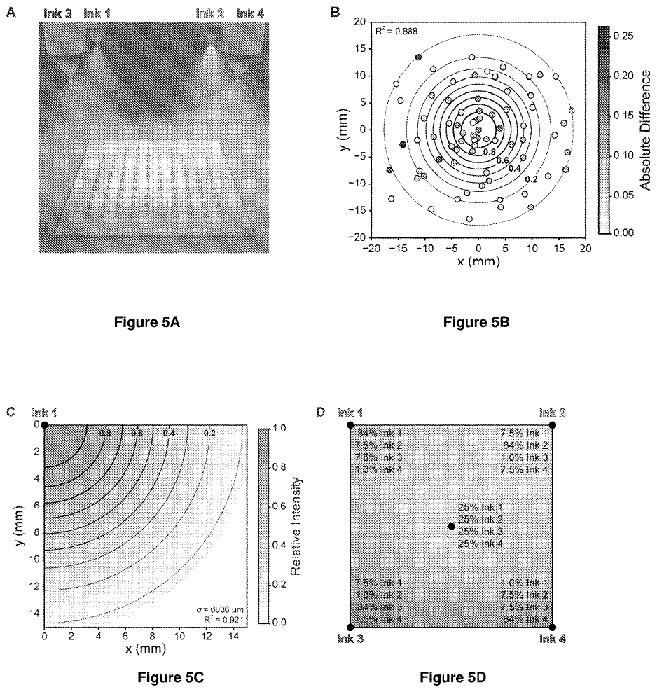

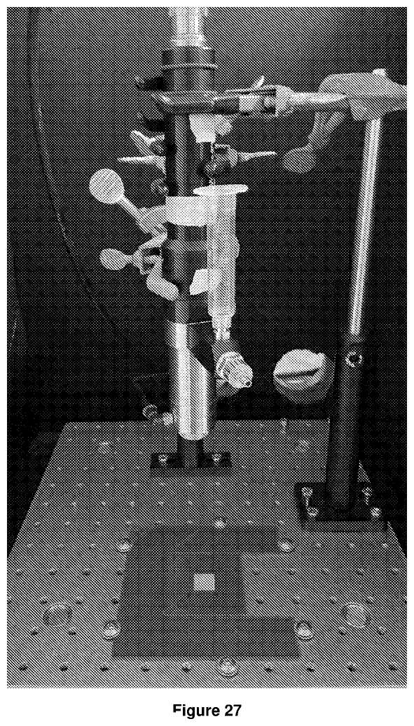

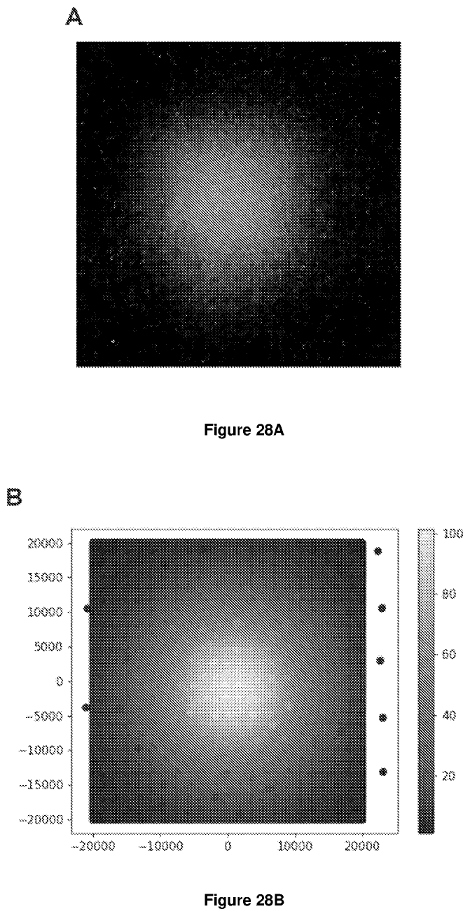

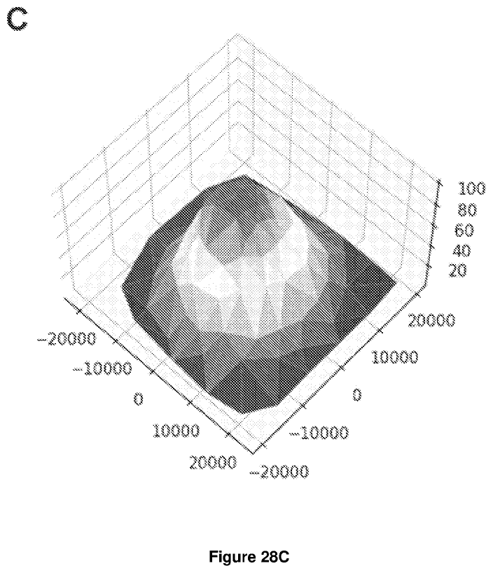

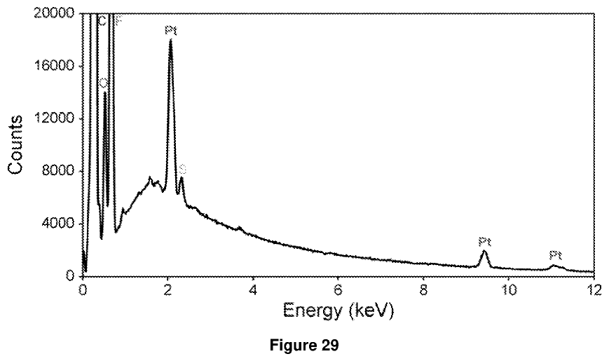

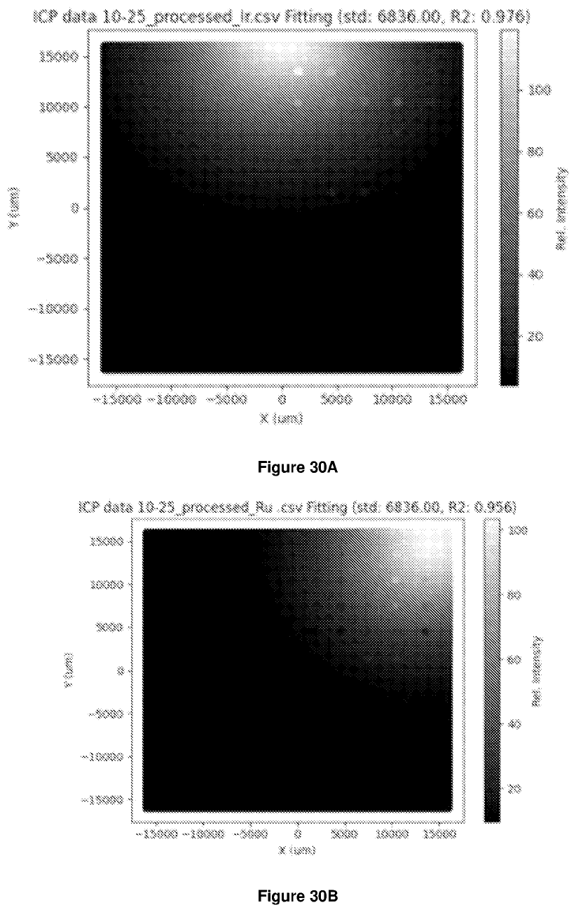

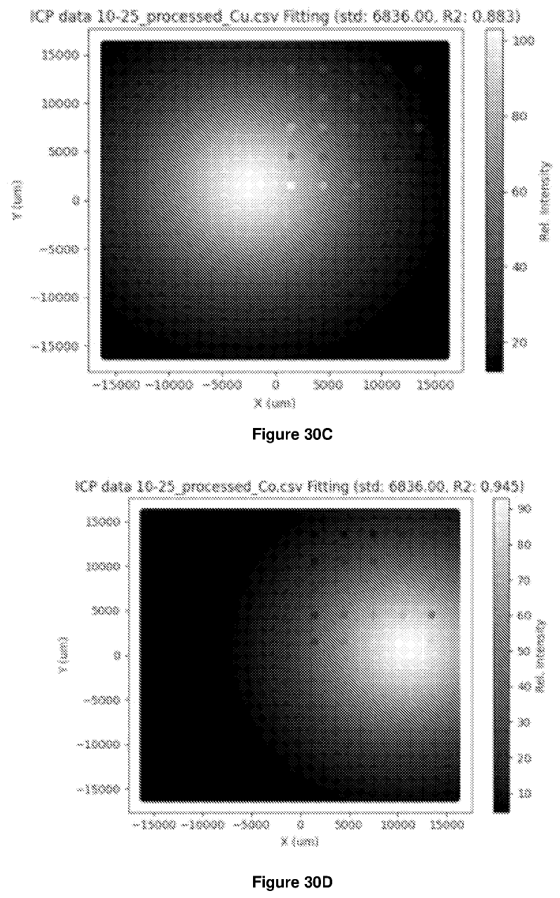

For megalibrary synthesis, the ink composition and volume at each pen tip in the array needs to be controlled independently. With pen arrays containing thousands, and up to millions, of individual pens, controlled inking can be accomplished using spray coating (FIG. 27). Spraying allows for radial distribution of multiple inks at precise positions of the pen array to create composition gradients (FIG. 5A). Qualitative analysis of the ink spray profile can be performed by spraying colored dye-containing inks onto a substrate and imaging the variation in color intensity to reveal a distinct Gaussian distribution (FIG. 28). More quantitative evaluation of the spray inking strategy was achieved with a combination of energy-dispersive X-ray spectroscopy (EDS) and inductively coupled plasma mass spectrometry (ICP-MS). First, a representative ink containing Pt was sprayed onto a carbon substrate then thermally annealed it to convert the sprayed substrate into a mixture of nanoparticles that can be readily characterized by EDS at precise positions (FIG. 29). The relative intensities of the Pt peaks were plotted against the coordinates of the substrate, and a Gaussian distribution was fit to the data. FIG. 5B depicts the contours of this spray intensity distribution and shows the deviation of each EDS data point from the modeled surface profile. Second, ICP-MS was used to probe multiple overlaid spray gradients. Four representative inks containing Ir, Ru, Cu, and Co were sprayed at the four corners of a 1.5×1.5 cm² pen array, which was then cut into 25 equal pieces, digested in 2% HCl and 2% HNO₃, and analyzed by ICP-MS (FIG. 30). The changes in metal concentration were again fit to Gaussian distributions and combined with the EDS analysis to give a singular fit for our spray profile intensity, which result in a sigma value of 6,836 μm (FIG. 5C). This analysis describes the variation in spray intensity as 100% at the center of the spray location (i.e., at a corner of the pen array), which then decreases to 8.9% at 1.5 cm away and to 1.2% at 2.1 cm away, which represent the adjacent corners or diagonal of the pen array, respectively. Finally, four separate spray profiles can be overlayed, centered around each of the four corners of the pen array to predict the composition gradients attainable in a four-spray experiment.

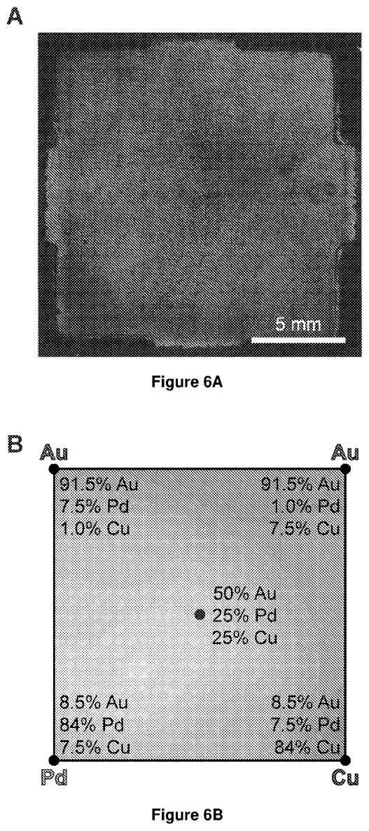

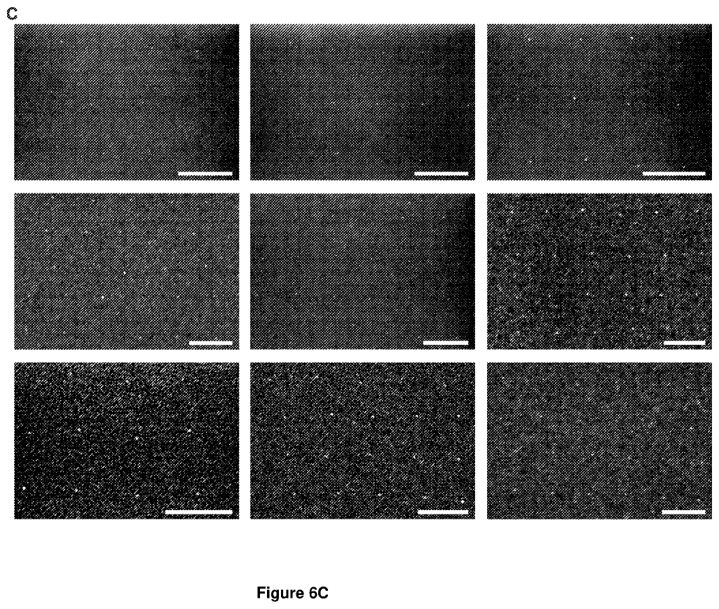

With this characterization of four-ink spray profiles, composition gradients can be readily determined for two- and three-component libraries by simply combining the requisite gradients since the spray profile at each corner is unaffected by the metal precursor identity. For example, a three-component Au—Pd—Cu megalibrary system was designed by spraying Au at two adjacent corners of a pen array and Pd and Cu at the other corners, respectively. Uniform patterning of 25×25 arrays of nanoreactors by each of the 90,000 pens on a 2.25 cm² polystyrene coated TiO₂ substrate is shown in FIG. 6A. The predicted elemental composition gradient is shown in FIG. 6B indicating that this megalibrary covers a nanoparticle design space from 8.5-91.5% Au, 1.0-84.0% Pd, and 1.0-84.0% Cu. Subsequent annealing yields a megalibrary with a total of 56,250,000 nanoparticles and 90,000 distinct metal compositions defined by the Au—Pd—Cu sprays. The ability to readily synthesize three- and four-component nanoparticle megalibraries is a significant advance over our previous two-component nanoparticle megalibrary work, with a >700-fold increase in the number of unique compositions patterned on a single chip. It is also possible to combine multiple metals in each corner to access even more elaborate composition gradients, if needed. Representative SEM images at multiple locations of the megalibrary confirm that single AuₓPd_{y}Cu_{z} nanoparticle formation occurs in each nanoreactor with varied ink compositions (FIG. 6C). Compositional analysis of these single nanoparticles on functional substrates is difficult because of the small particle diameters (<30 nm) and intense substrate signal during SEM-EDS or time-of-flight secondary ion mass spectrometry (TOF-SIMS). However, previous work using scanning transmission electron microscopy (STEM)-EDS to characterize nanoparticles synthesized by SPBCL on silicon nitride membranes established strong correlations between the ink composition and the nanoparticle composition. This predictable control of composition is advantageous for accelerating the materials discovery workflow by eliminating the need for in-depth structural characterization of every material synthesized, which is impractical at the scale of thousands to millions of materials per megalibrary.

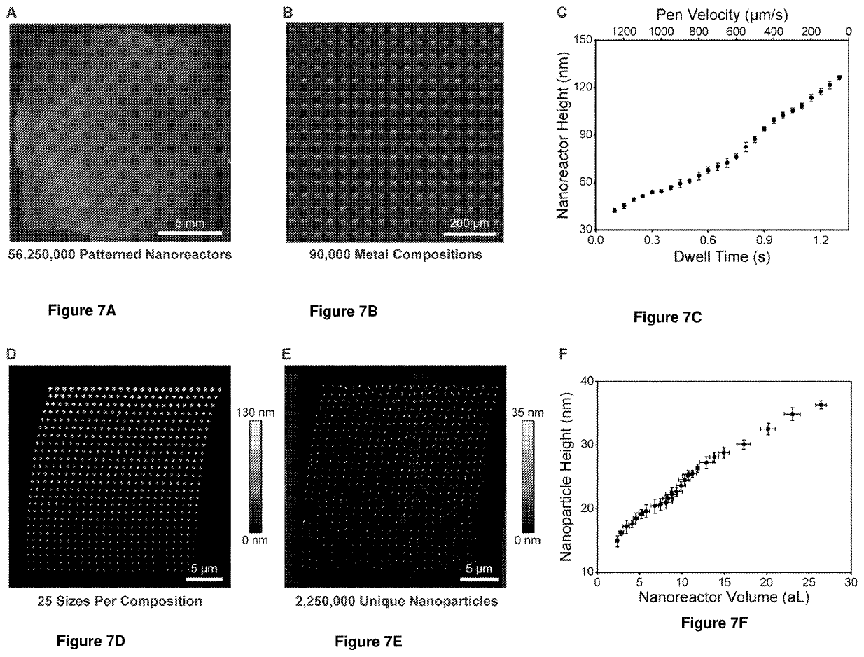

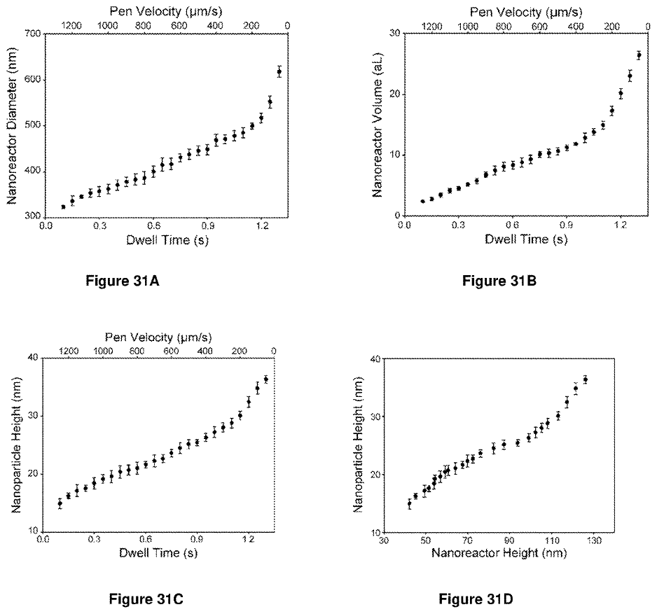

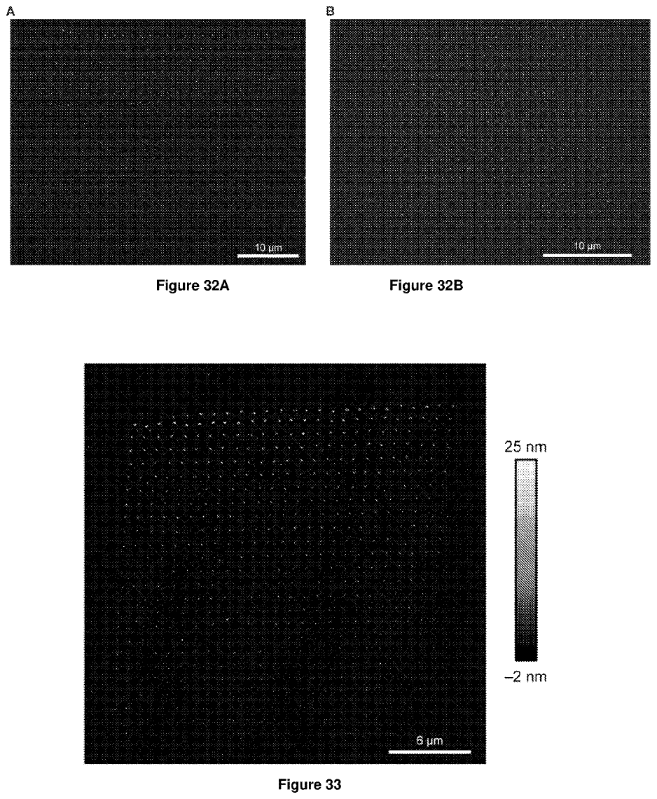

The method of the disclosure was demonstrated to be useful in generating libraries with nanoparticle size gradients. Feature size control in scanning probe lithography is well-established and accomplished by varying the pen velocity, the dwell time between the pen and substrate, or the force between the pen and substrate. For SPBCL, these parameters can be used to vary the nanoreactor volume, which dictates the resulting nanoparticle size, or the precursor concentration in the ink can be changed to control the nanoparticle size. To introduce size control to library synthesis without limiting our composition control, each individual pen tip can be used to create 90,000 separate size gradients. A 25×25 patterns of Au—Pd—Cu nanoreactors was synthesized where both the pen velocity was increased from 50 to 1250 μm/s and the dwell time was decreased from 1.3 to 0.1 s in 25 increments. This resulted in each pen patterning 25 differently sized nanoreactors with 25 replicates each. Large area optical microscopy shows the 2.25 cm² pattern containing 56.25 million total nanoreactors with each of the 90,000 pen tips creating a pattern with a distinct composition (FIG. 7A). A magnified image begins to reveal the nanoreactor size gradient created by each pen tip (FIG. 7B), and AFM height analysis clearly shows that the nanoreactor height and diameter both increase as the dwell time increases and the pen velocity decreases with minimal size variance for nanoreactors patterned with identical parameters (FIGS. 7C, 7D, 31). The nanoreactor heights and diameters were controlled between 126.2±1.3 to 42.2±1.2 nm and 617.6±12.3 to 323.5±3.7 nm, respectively (Table 1). The approximate calculated nanoreactor volumes ranged from 26.4±0.7 to 2.3±0.2 attoliters.

TABLE 1
Summary of nanoreactor and nanoparticle dimensions after
patterning with different dwell times and pen velocities.

| | Dwell | Velocity | Nanoreactor | Nanoreactor | Nanoreactor | Nanoparticle |
|---|---|---|---|---|---|---|
| Row | Time (s) | (μm/s) | Height (nm) | Diameter (nm) | Volume (aL) | Height (nm) |
| 1 | 1.30 | 50 | 126.2 ± 1.3 | 617.6 ± 12.3 | 26.4 ± 0.7 | 36.3 ± 0.6 |
| 2 | 1.25 | 100 | 121.5 ± 2.3 | 552.1 ± 13.4 | 23.0 ± 0.9 | 34.8 ± 1.0 |
| 3 | 1.20 | 150 | 117.3 ± 1.9 | 516.9 ± 10.8 | 20.2 ± 0.8 | 32.5 ± 0.9 |
| 4 | 1.15 | 200 | 113.3 ± 2.2 | 499.6 ± 6.8 | 17.3 ± 0.8 | 30.1 ± 0.7 |
| 5 | 1.10 | 250 | 108.2 ± 1.8 | 484.9 ± 11.6 | 14.9 ± 0.6 | 28.8 ± 0.8 |
| 6 | 1.05 | 300 | 105.3 ± 1.7 | 478.1 ± 11.1 | 13.8 ± 0.5 | 28.0 ± 0.8 |
| 7 | 1.00 | 350 | 102.3 ± 1.9 | 471.2 ± 9.7 | 12.9 ± 0.8 | 27.2 ± 0.9 |
| 8 | 0.95 | 400 | 99.1 ± 1.9 | 468.4 ± 13.6 | 11.9 ± 0.2 | 26.3 ± 0.7 |
| 9 | 0.90 | 450 | 93.8 ± 1.3 | 448.7 ± 11.0 | 11.2 ± 0.4 | 25.4 ± 0.6 |
| 10 | 0.85 | 500 | 87.3 ± 1.9 | 445.9 ± 10.2 | 10.7 ± 0.6 | 25.2 ± 0.7 |
| 11 | 0.80 | 550 | 82.3 ± 2.8 | 437.9 ± 11.7 | 10.3 ± 0.7 | 24.5 ± 0.9 |
| 12 | 0.75 | 600 | 76.1 ± 1.8 | 431.1 ± 8.9 | 9.9 ± 0.6 | 23.6 ± 0.6 |
| 13 | 0.70 | 650 | 72.4 ± 2.8 | 416.7 ± 12.6 | 9.3 ± 0.7 | 22.7 ± 0.7 |
| 14 | 0.65 | 700 | 69.8 ± 2.2 | 415.3 ± 14.3 | 8.8 ± 0.7 | 22.2 ± 1.0 |
| 15 | 0.60 | 750 | 67.5 ± 2.3 | 400.8 ± 12.3 | 8.3 ± 0.6 | 21.6 ± 0.6 |
| 16 | 0.55 | 800 | 64.1 ± 2.4 | 387.0 ± 13.4 | 8.1 ± 0.7 | 21.0 ± 1.0 |
| 17 | 0.50 | 850 | 60.7 ± 1.5 | 383.1 ± 12.1 | 7.4 ± 0.7 | 20.7 ± 0.9 |
| 18 | 0.45 | 900 | 59.2 ± 2.6 | 378.0 ± 10.1 | 6.7 ± 0.4 | 20.3 ± 1.1 |
| 19 | 0.40 | 950 | 56.7 ± 1.2 | 371.2 ± 11.3 | 5.7 ± 0.4 | 19.6 ± 1.0 |
| 20 | 0.35 | 1000 | 54.2 ± 0.9 | 362.8 ± 10.9 | 5.1 ± 0.3 | 19.1 ± 0.7 |
| 21 | 0.30 | 1050 | 53.9 ± 1.0 | 357.5 ± 10.4 | 4.5 ± 0.3 | 18.4 ± 1.0 |
| 22 | 0.25 | 1100 | 51.4 ± 0.6 | 353.6 ± 9.1 | 4.1 ± 0.4 | 17.6 ± 0.5 |
| 23 | 0.20 | 1150 | 49.3 ± 1.1 | 345.8 ± 3.3 | 3.4 ± 0.3 | 17.1 ± 1.0 |
| 24 | 0.15 | 1200 | 44.9 ± 1.5 | 336.9 ± 10.5 | 2.8 ± 0.2 | 16.3 ± 0.4 |
| 25 | 0.10 | 1250 | 42.2 ± 1.2 | 323.5 ± 3.7 | 2.3 ± 0.2 | 14.9 ± 0.9 |

After thermal annealing, a megalibrary of Au—Pd—Cu nanoparticles was formed, and AFM shows the resulting size gradient (FIG. 7E). The range of nanoparticle heights was 36.3±0.6 to 14.9±0.9 nm, which gives a nanoparticle step size of approximately 0.9 nm from one row to the next. The correlation between nanoreactor volume and nanoparticle size is depicted in FIG. 7F. Additional SEM images of the Au—Pd—Cu nanoparticle size gradient as well as a Au nanoparticle size gradient are shown in FIG. 32. Similar patterning strategies can control the nanoparticle size range; for example, faster pen velocities and shorter dwell times yielded a gradient of ~5-25 nm nanoparticles (FIG. 33). When taking both the size gradients and composition gradients into consideration, this megalibrary with a total of 56,250,000 nanoparticles contains 2,250,000 distinct compositions and sizes that are individually controlled. This corresponds to precise synthetic control of 1 million unique nanoparticles per cm², which is the largest megalibrary to date and the highest level of single particle control demonstrated in parallel using PPL and SPBCL. In the broader context of nanocombinatorial materials libraries, this megalibrary accesses a greater number of discrete materials while providing a higher level of synthetic control compared to drop-casting, ink-jet printing, or gradient thin films prepared by vapor deposition.

While SPBCL and PPL synthesize nanoparticle patterns with control over positioning, substrate, composition, and size, fabrication requirements result in a density of only 1 nanoparticle per μm². This makes the detection of nanoparticle activity a significant challenge for certain applications, such as catalysis, where typical nanoparticle or single atom catalyst loading densities are several orders of magnitude higher. As such, strategies that can amplify catalyst activity into an easily observed proxy are needed. We devised a highly sensitive optical readout in which the signal can accumulate over time in a spatially selective manner as a proxy for catalyst turnover to tackle this challenge and demonstrate photocatalysis as a practical application for megalibrary screening. First, a uniform pattern of Au nanoparticles on a nanocrystalline anatase TiO₂ thin film was employed in photocatalysis experiments that also confirm that nanoparticle synthesis on polystyrene coated TiO₂ leads to the formation of junctions between the Au and the TiO₂ semiconductor substrate, which is required for charge transport.

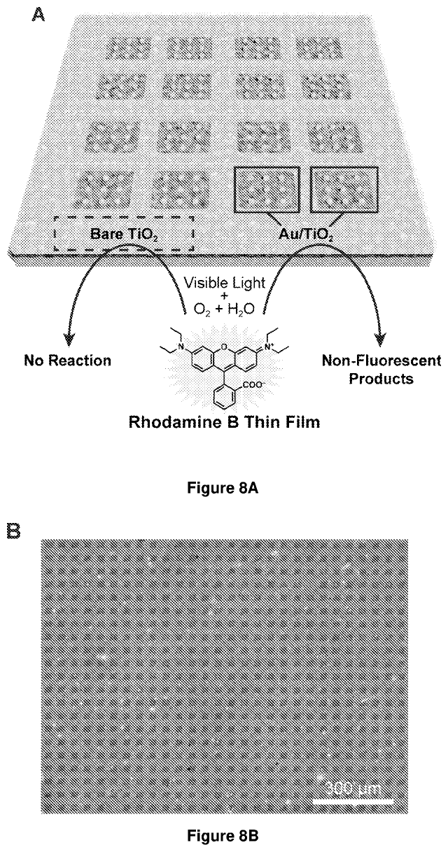

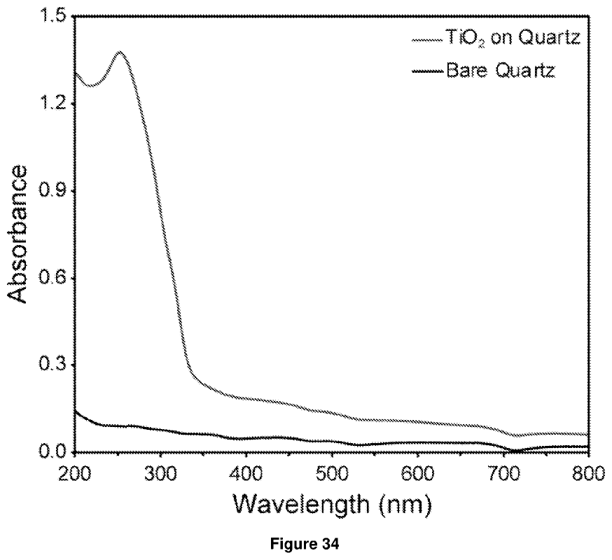

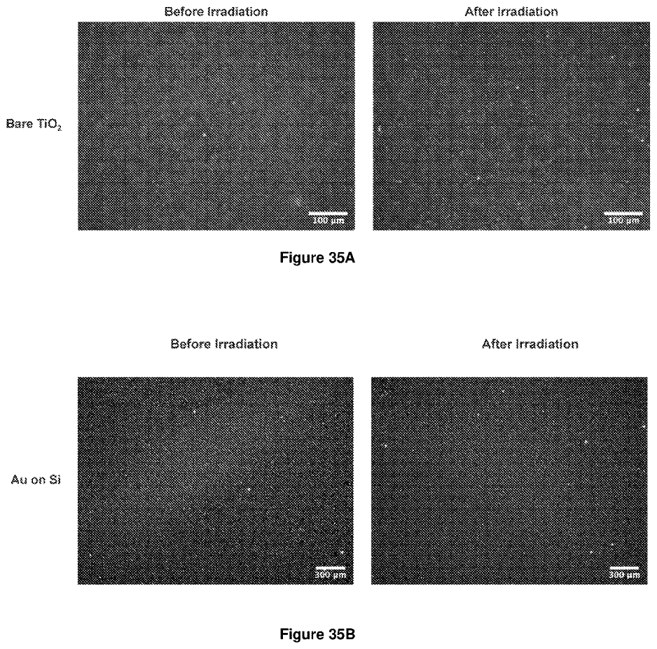

Specifically, patterns of 13±1 nm Au nanoparticles on TiO₂ were used as catalysts for the photocatalytic degradation of rhodamine B as a model organic pollutant. Such pollutants must be converted into benign substances for remediation, and much effort has identified photocatalytic pathways that use water and oxygen to drive dye degradation through the generation of reactive oxygen species or direct reduction and oxidation mechanisms. TiO₂ itself can catalyze the degradation of rhodamine B using UV light, but the addition of Au nanoparticles as a cocatalyst is a viable strategy to boost performance by enhancing visible light absorption, charge separation, or both by taking advantage of the localized surface plasmon resonance (LSPR) of Au. Typically, photocatalytic dye degradation studies are performed with dissolved dye solutions; however, the unique site-specific patterning with PPL offers an approach for site-specific photocatalysis (FIG. 8A). First, we synthesized a repeating pattern of 625 Au nanoparticles with 1 μm spacing in 25×25 μm² squares. Each square array of Au/TiO₂ pattern is separated from neighboring arrays by 25 μm of bare TiO₂ substrate. This pattern was subjected to air plasma to remove any carbon residue on the particles from incomplete nanoreactor removal that may hinder light absorption or catalysis. Then, a thin film of rhodamine B dissolved in an amphiphilic polymer was applied on top of the Au/TiO₂ pattern. The polymer was added to facilitate hydration and oxygen diffusion by increasing the film thickness without adding excessive dye that can hinder light absorption by the underlying catalyst. Next, this coated catalyst platform was placed in a chamber filled with humidified oxygen and irradiated using a 400 W Xe arc lamp for 30 min. Under UV light irradiation where TiO₂ is an effective catalyst for rhodamine B degradation, we observe a uniform loss in fluorescence over the patterned substrate, indicating that the Au cocatalysts do not yield an observable enhancement in degradation over bare TiO₂. In contrast, visible light irradiation using a 435 nm long-pass filter cannot excite electrons over the TiO₂ bandgap (FIG. 34), but it can excite the Au LSPR to generate hot electrons and promote photocatalysis.^{61,68} Indeed, fluorescence microscopy post-irradiation with visible light revealed a loss in rhodamine B fluorescence in a square pattern confined to the square patterns of Au nanoparticles (FIG. 8B). Thus, the patterned Au nanoparticles were contact with the underlying anatase TiO₂ substrate, and this combined platform was more effective for the visible light photocatalytic degradation of rhodamine B in the solid state than bare TiO₂. Control experiments using Au nanoparticle patterns on silicon or non-patterned TiO₂ did not show any change in fluorescence under visible light (FIG. 35). This demonstration of visible light photocatalysis confirms the synergy of Au and TiO₂ to overcome the limitations of the wide band gap of TiO₂. Furthermore, the spatial positioning of Au nanoparticles by PPL adds a unique level of spatial catalysis control, and the use of a fluorophore interfaced with the patterned substrate proves to be a sufficient proxy to rapidly gauge catalyst activity with high sensitivity.

The method of the disclosure can be used for a variety of materials applications, including electrocatalysis, luminescence, and durability. For example, megalibraries formed in accordance with the disclosure were used for ultrafast materials discovery using photocatalytic degradation of organic pollutants as a facile indicator of relative catalytic activity. For nanoparticle-TiO₂ photocatalyst platforms, Au has been extensively studied. However, a broad range of nanoparticle-semiconductor photocatalysts have demonstrated high activity, including various Pd- and Cu-based platforms because of their plasmonic behavior. Recently, bi- and trimetallic catalysts have been explored for photocatalytic degradation of organic pollutants and have demonstrated enhanced activity compared to the mono-metallic analogs, including AgCu, AuAg, and AuPdRu. The megalibrary platform was used to quickly survey the photocatalyst design space comprising Au—Pd—Cu trimetallic nanoparticles interfaced with TiO₂. Our strategy for using fluorescence turn-off of rhodamine B thin films during degradation as a proxy for catalyst turnover was applied to the megalibrary for high-throughput parallel screening. Through this method, the relative photocatalytic performance of a total of 90,000 unique nanoparticle compositions with 625 replicates of each are characterized simultaneously since the fluorescence response from nanoparticles patterned by each pen tip can be spatially resolved.

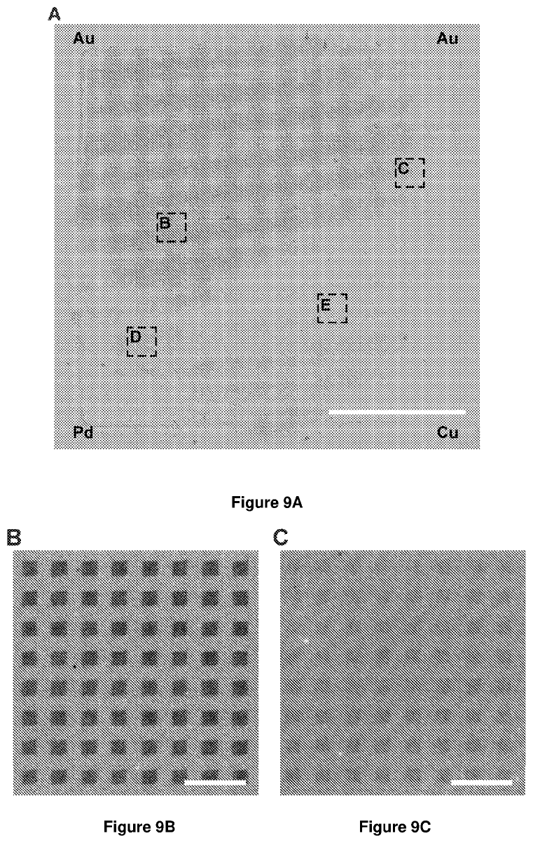

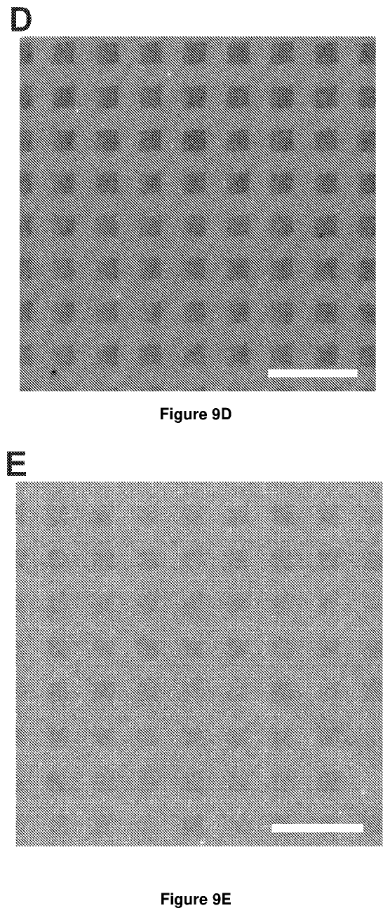

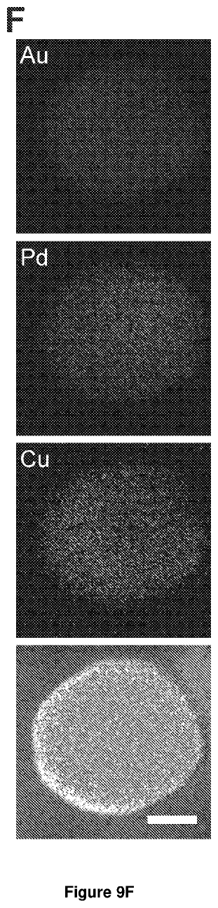

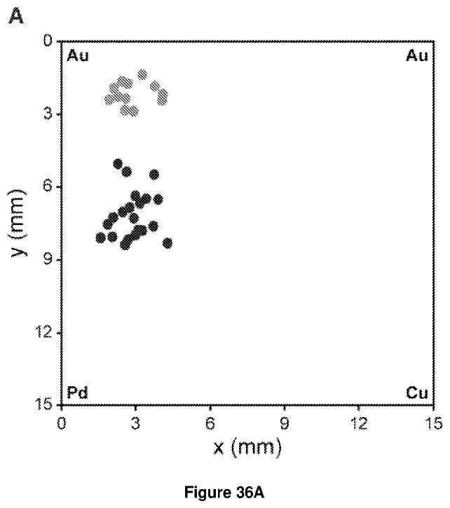

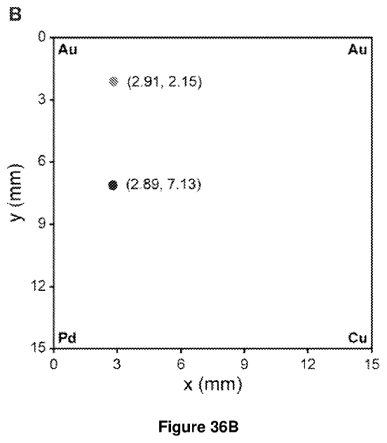

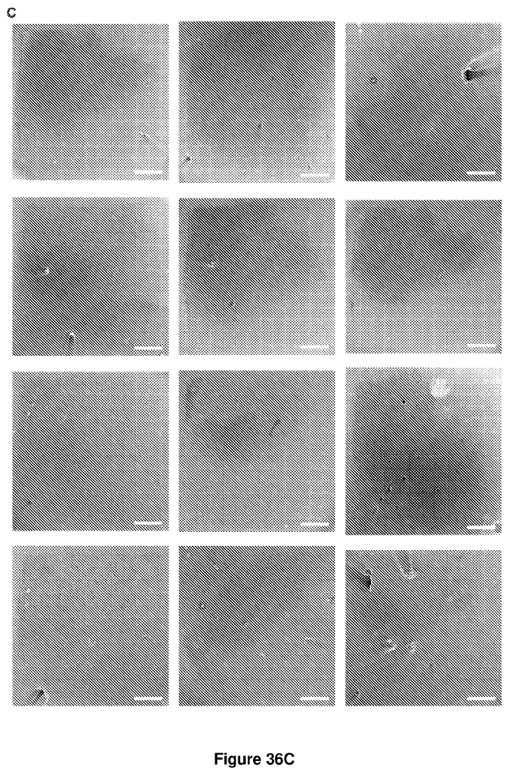

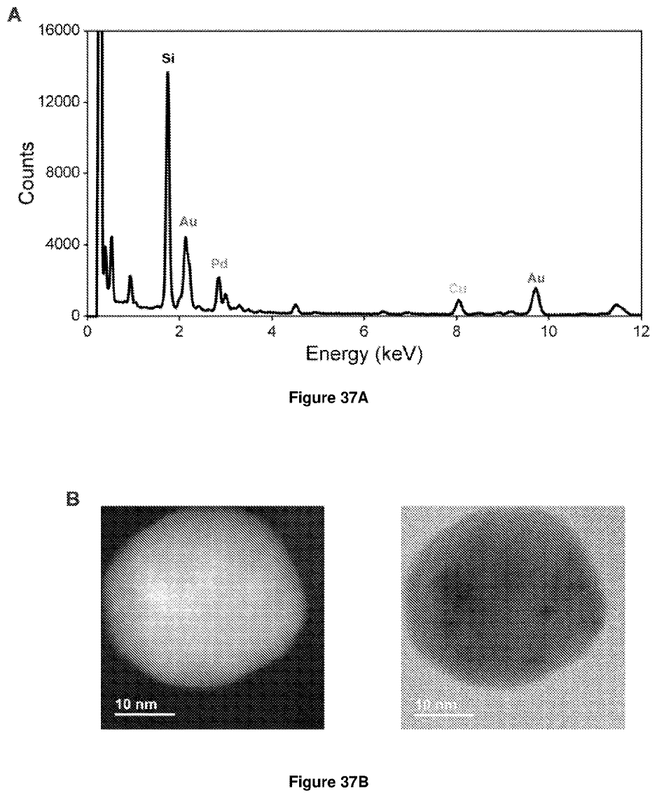

After irradiating the rhodamine B coated Au—Pd—Cu megalibrary with visible light for 30 min, the 2.25 cm² pattern was imaged using fluorescence confocal microscopy. FIG. 9A shows an entire megalibrary post-photocatalysis with square patterns of reduced fluorescence intensity that correspond with the positioning of nanoparticle patterns with intensities that vary with the compositional gradients. The differing extents of fluorescence loss indicate variation in catalytic activity. Importantly, each 25×25 μm² square of reduced fluorescence represents an individual catalyst performance experiment since each pen tip pattern constitutes a distinct elemental composition. Thus, 90,000 experiments are performed in parallel in only 30 min. FIGS. 8B-E show magnified images of selected regions of the megalibrary photocatalysis demonstrating that the extent of fluorescence turn-off depends on the nanoparticle composition. Multiple replicates were performed to account for any errors due to incomplete patterning or defects due to dust or pinholes during spin coating of rhodamine B. To identify the highest performing catalysts, each megalibrary replicate was analyzed to identify the region(s) of lowest fluorescence intensity, which were plotted in FIG. 36 to reveal two clusters of high catalytic activity. The centroids of the clusters were identified, and using the spray profile analysis from FIG. 6B, we discovered Au_{0.53}Pd_{0.38}Cu_{0.09} as the best performing photocatalyst within this megalibrary composition space and under these applied photocatalysis conditions. The second highest performer was identified as Au_{0.85}Pd_{0.12}Cu_{0.03}. Notably, the relative decrease in fluorescence intensity for these catalysts is larger than that observed in FIG. 8 using Au nanoparticles, suggesting a higher catalyst performance for the trimetallic species. Beyond materials discovery, megalibrary screening generates a large volume of structure-function relationship data. For example, the Au—Pd—Cu megalibrary shows that high Au content generally leads to good photocatalyst performance, and incorporation of greater than ~20% Cu or ~60% Pd content has detrimental effects on catalysis. Regions of the megalibrary with lowest Au content were consistently the worst performers. To further characterize the discovered photocatalyst, we re-synthesized Au_{0.53}Pd_{0.38}Cu_{0.09} nanoparticles on silicon nitride membranes via SPBCL and dip-pen nanolithography (DPN) for structural characterization. STEM-EDS mapping of a single nanoparticle reveals homogeneous mixing of the Au, Pd, and Cu components (FIGS. 8F, S28), and the atomic composition was approximated to be 47% Au, 33% Pd, and 20% Cu. Additional catalyst synthetic scale up and bulk performance testing will be the focus of future work. Overall, the reactive fluorescent thin film is a highly sensitive proxy for catalytic performance, and when combined with nanomaterial spatial positioning using lithography, the catalyst testing can be performed in parallel at an unmatched scale.

The method of the disclosure can accelerate exploration of the materials genome by allowing work on metallic, semiconductor, and insulator substrates, including highly roughened ones, like TiO₂ particle coated structures, and smooth electrodes, like glassy carbon. Millions of nanoparticles can be synthesized per megalibrary with each nanoparticle having an individually addressable composition, size, and position. Coupling megalibrary synthesis with materials screening techniques of comparable speeds provides an unprecedented level of high-throughput experimentation (HTE) to discover functional materials for a broad set of applications. Importantly, fluorescent molecule-based sensors provide the sensitivity required to rapidly screen these megalibraries with micron resolution.

Methods of the disclosure can offer a fast and efficient way to produce libraries and megalibraries over a variety of substrate. For example, an entire materials discovery flow can require 30 min to pattern the megalibrary, 26 h of thermal annealing, 30 min of photocatalysis, and 30 min of fluorescence imaging. These time frames, which allow one to look at ~56 million structures simultaneously, are comparable to that required to look at an individual structure serially. Universal substrate coatings used in the methods of the disclosure can streamline megalibrary synthesis and make multiple iterations of megalibrary synthesis and screening for discovery and optimization straightforward. This will lead to the accumulation of massive structure-function relationship data sets and in the process empower machine learning algorithms. Additionally, by following the lead of sensor design in other fields like chemical biology, new fluorescent sensor films can be designed to chemoselectively detect products of catalysis in order to screen catalyst selectivity and activity simultaneously. Taken together, these data suggest that by eliminating substrate requirements for scanning probe lithography, one can greatly expand the breadth of synthetic design in each megalibrary, which when combined with the high resolution and throughput of catalyst screening using fluorescent thin films is poised to rapidly accelerate materials discovery.

### EXAMPLES

Methods and Materials. Polystyrene (atactic; Mₙ 4,200 M_{w}/Mₙ=1.05; 10,000 M_{w}/Mₙ=1.09; 25,000 M_{w}/Mₙ=1.04; 51,000 M_{w}/Mₙ=1.03), Poly(2-vinylpyridine)-b-poly(ethylene oxide) (Mₙ 1,500-b-2,800 M_{w}/Mₙ=1.11), polyethylene (Mₙ=10,400 M_{w}/Mₙ=1.04), and polypentafluorostyrene (Mₙ=17,000 M_{w}/Mₙ=1.16) were purchased from Polymer Source and used as received. HAuCl₄×3H₂O (≥99.9%), Co(NO₃)₂×6H₂O (99.999%), Cu(NO₃)₂×2.5H₂O (99.99%), Pd(NO₃)₂×2H₂O (~40% Pd basis), AgNO₃ (99.9999%), H₂PtCl₆×6H₂O (ACS reagent grade), HNO₃ (70%, redistilled, ≥99.999%), titanium isopropoxide, acetylacetone, ethanol, toluene, rubrene, perylene, and rhodamine B were purchased from Sigma-Aldrich and used as received. Ionomer Sustainion XB7 5% in ethanol was purchased from Fuel Cell Store. Sylgard 184 PDMS was purchased from Fisher Scientific. Ultra-high purity H₂ (99.999%), Ar (99.999%), and O₂ (99.994%) were purchased from Air-Gas. Water used in all experiments was Millipore ultrapure water (18.2 MW×cm).

Silicon substrates (As doped, 0.5 mm thick) were purchased from University Wafer and cut into 2×2 cm² pieces. Glassy carbon plate electrodes (2×2 cm², 3-5 mm thick, diamond polished Rₐ<50 nm) were purchased from HTW Hochtemperatur-Werkstoffe. Polycrystalline tungsten, ultra-nanocrystalline diamond on silicon (1 μm thick, 1 nm Rₐ), boron nitride film on silicon (24 nm thick, amorphous, sputtered), and silicon carbide film on silicon (2.2 μm thick, 3C structure, 1 nm Rₐ, PECVD) were purchased from MTI Corporation and used as received. Polymer pen arrays were purchased from TERA-print, or were fabricated as previously reported.¹

Scanning electron microscopy was performed using a Hitachi SU8030 SEM with 5.0 kV acceleration voltage, 15 μA emission current, and high probe current for secondary electron imaging, while a JEOL JSM-7900FLV SEM with 5.0 kV acceleration voltage and large probe current was used for back-scattered electron imaging and SEM-EDS. SEM-EDS spectra were acquired with 20.0 kV accelerating voltage and analyzed using AZtec (Oxford Instruments). DPN/SPBCL on TEM membranes and STEM-EDS characterization were performed as previously described.² Atomic force microscopy was performed using a Bruker Dimension Icon AFM in tapping mode with an NCHR probe, and data analysis was performed using NanoScope Analysis. Optical microscopy was performed using a Zeiss Axio Imager with appropriate dark-field, bright-field, or fluorescence filters. Profilometry was performed using a Veeco Dektak 150 surface profiler. Confocal fluorescence microscopy was performed using a Zeiss laser scanning microscope 800 with a 10× objective lens using Zen 2.3 software. Thermogravimetric analysis was performed using a Netzsch Simultaneous Thermal Analysis system or a TA Instruments Discovery TGA system under a N₂ flow and a temperature ramp rate of 10° C./min. Contact angle measurements were performed using a Ramé-Hart goniometer. Electron beam evaporation was performed using a Pro-Line PVD 75 system (Kurt J. Lesker). A Lindberg Blue tube furnace with quartz tubes was used for thermal annealing. Grazing incidence X-ray diffraction was performed with a Smartlab Gen2 3 KW system. ICP-MS was performed using a Thermo Element2 High Resolution Magnetic Sector Field instrument. Air plasma treatments were performed in a Plasma Etch, Inc. plasma cleaner. The Xe arc lamp light source, power supply, and 435 nm long-pass filter used for photocatalysis were purchased from Newport Corporation.

Preparation of Pyrolyzed Photoresist Film Substrates. In a clean room, a 10 cm diameter silicon wafer (As doped) was spin coated with S1813 positive photoresist at 3,000 rpm and then baked at 115° C. for 2 min. This coating was repeated to give four layers of photoresist on the silicon substrate. The coated wafer was cut into 2×2 cm² pieces and then inserted into a tube furnace. Under a flow of 100 standard cubic centimeters per minute (sccm) 5% H₂ in Ar, the samples were heated to 1,000° C. with an 8.5 h ramp and then held at 1,000° C. for 1 h before slowly cooling to room temperature.

Preparation of Sol-Gel Titania Substrates. The TiO₂ film was prepared with slight modifications to previous reports.^{3,4} First, a precursor solution was prepared by mixing 0.6 mL acetylacetone in 2.5 mL of ethanol followed by the addition of 0.9 mL titanium isopropoxide. Next, 0.75 mL of the precursor solution was spin coated onto a 10 cm silicon wafer at 5,000 rpm for 60 seconds. The coated substrate was placed onto a hot plate at 100° C. for 2 min, cut into 2×2 cm² pieces, and then annealed at 600° C. in a tube furnace under air for 2 h.

Substrate Preparation and Polystyrene Thin Film Formation. The substrates were first washed with isopropanol and dried under a stream of N₂. A 5% w/v solution of polystyrene (Mₙ=10,000) in toluene was prepared and passed through a 0.2 μm PTFE syringe filter. Polystyrene thin films were then applied to the substrates by spin coating with dynamic application of the polystyrene solution at 2,500 rpm followed by baking at 110° C. for 2 min on a hot plate.

Alternative Thin Film Formation. The same procedure was followed as for the polystyrene thin film formation with adjustments for solubility. Polyethylene (Mₙ=10,400) is dissolved in 1,2-dichlorobenzene at a concentration of 0.2% w/v. Polypentafluorostyrene (Mₙ=17,000) is dissolved in hexafluorobenzene at a concentration of 1% w/v. Rubrene is dissolved in toluene at a concentration of 0.5% w/v. Perylene is dissolved in chloroform at a concentration of 1% w/v.

Preparation of Polymer Pen Arrays. Pen arrays were fabricated with modifications to previous reports.¹ Silicon masters etched with arrays of inverted pyramids with 20 μm bases and 50 μm pitches over 4 cm×4 cm were purchased from Hawk Semiconductor. Pieces of Scotch tape were placed along the edges of the master to make rails ~175 nm thick. Sylgard 184 PDMS was prepared and degassed then added to the center of the master. A razor blade was passed along the tape rails to evenly spread the PDMS layer, ensuring that no air bubbles or dust particles are included. This was allowed to settle at room temperature for 5 min, then placed in an oven at 80° C. for 15 min. Next, additional PDMS was added to the center of the master, and a 2 in ×2 in × 1/16 in glass plate (air plasma treated, 30 W, 2 min) was placed on top. The PDMS was allowed to spread completely under the glass plate, which was then secured in place using additional glass slides, and then placed in an oven at 80° C. overnight. Excess cured PDMS was removed from the edges of the pen array, which was then peeled out of the master. The pen array was then covered with a custom-made mask before using electron beam evaporation to apply 10 nm of Cr then 150 nm of Au.

Spray Inking of Pen Arrays. A pen array was first blown with N₂ gas to remove any dust particles and treated with air plasma at 30 W for 2 min. A custom-made mask was applied to the pen array to only expose the central 1.5 cm×1.5 cm area for patterning use. The pen array was secured underneath a spray gun such that the nozzle was 11.5 cm above the pen array and centered over one corner of the exposed area of the pen array. An eco-SPRAY (ViscoTec) spray gun was used to iteratively spray 5 μL of ink at each corner of the array, allowing for drying in between each spray. The spray controller was programmed to deliver 5 μL of ink at a rate of 3 mL/min and a pressure of 0.5 bar. After spraying each corner, the entire pen array was placed in an environment of 100% relative humidity for 10 s before allowing to dry to improve the spray homogeneity.

Nanoreactor Patterning and Nanoparticle Synthesis. Precursor inks were prepared as 5% poly(ethylene oxide)-b-poly(2-vinylpyridine) (PEO-b-P2VP) block copolymer w/v aqueous solutions with 1.0 mM or 4.0 mM metal salt. These values give a total metal to pyridine group molar ratio of 1:16 or 1:4, respectively. For non-acidic metal salts, 2 μL of 1 M HNO₃ was added per mL of ink prepared to acidify it. This ink solution was left to shake overnight in the dark before use. Pen arrays were treated with air plasma at 30 W for 2 min, then a spray gun was used to apply the ink solution(s) onto the 1.5×1.5 cm² array of pen tips as described above. The inked pen array and polystyrene coated substrate were attached to a TERA-print M-series lithography instrument. A lithography experiment was performed in an environment of 80% relative humidity at room temperature such that a 25×25 pattern of nanoreactors was deposited with 1 μm spacing. Each droplet was made by moving the substrate into contact with the pen array at a velocity of 100 μm/s until a contact force of 1,800-1,900 mN was obtained, and this force was maintained for 1 s followed by retraction of the substrate and continuation of the patterning. After characterization of the nanoreactor patterning, thermal annealing in a tube furnace was performed under a 100 sccm flow of H₂ with a 1 h ramp from room temperature to 150° C., then a 6 h ramp from 150° C. to 240° C., followed by a hold at 240° C. for 12 h, then a ramp to 600° C. over 1 h and a hold at 600° C. for 6 h, followed by cooling to room temperature.

Analysis of Spray Profiles. For EDS analysis, a 100 mM Pt(NH₃)4(NO₃)₂ ink with 5% PEO-b-P2VP was prepared. A carbon paper substrate with a microporous layer was cut into a 4 cm×4 cm piece, and 5 μL was sprayed onto the center and allowed to dry. The sprayed substrate was placed in a tube furnace under a 100 sccm flow of H2, heated to 600° C. in 1 h and then held at 600° C. for 6 h to form Pt nanoparticles dispersed on the carbon substrate. EDS was performed with 20 kV accelerating voltage and sampled at random positions over an approximately 3 cm×3 cm area centered around the middle of the spray position. The peak for the Pt Mₐ line was integrated and used as a proxy for the local metal concentration.

For ICP-MS analysis, four separate inks containing 5% PEO-b-P2VP with 1.0 mM of Ir, Ru, Cu, or Co metal salt precursors. A PDMS pen array substrate was sprayed with 5 μL of each ink at the four corners of the center 1.5 cm×1.5 cm area, respectively. The sprayed PDMS pen array substrate was then cut into 25 equal pieces, which were then individually digested in solutions containing 2% HCl and 2% HNO₃ overnight before injection into the ICP-MS instrument.

For fitting data to 2D Gaussian distributions, EDS and ICP-MS intensity data were first normalized to relative intensities and assumed to be in the center of each screening region. Spray patterns were presumed radially symmetric so a single sigma value could be fitted using a 2D Gaussian function:

$$I = {ae}^{( \frac{{( x - {x}_{0} )}^{2} + {( y - {y}_{0} )}^{2}}{2 {σ}^{2}} )} + b$$

where a is amplitude, (x₀,y₀) are spray gun coordinates with respect to the substrate, s is standard deviation of the spray gun, and b is a vertical offset fitting parameter. The same gun is used across every dataset, so it is assumed that its s will remain constant across different sprays. To find a universal s for the spray gun over all spray datasets, we iteratively define a standard deviation in the range of 3000 to 15000 μm with 1 μm steps and then fit every spray dataset with reasonable physical boundaries (e.g., restricting (x₀,y₀) within +3000 μm of the originating corner). Once every possible s has been fitted against, the s that maximizes the average R² over all datasets is chosen—for this spray gun, the value is 6836 μm.

Photocatalytic Dye Degradation. A pattern of nanoparticles was first fabricated on a TiO₂ substrate. After the thermal annealing under H₂, the sample was treated with air plasma at 30 W for 2 min for complete removal of any organic residue from the nanoreactors and re-oxidation of the TiO₂ surface that may hinder the catalyst performance of the Au/TiO₂ pattern. An ethanol solution was prepared by mixing equal volumes of 1 mg/mL rhodamine B and 5% XB7 ionomer in ethanol, and this solution was then spin coated on top of a patterned sample at 3,000 rpm. The sample was affixed to a glass slide using carbon tape and placed inside of a quartz chamber. O₂ gas was passed through a water-filled bubbler heated at 90° C. and flowed into the quartz chamber. A 400 W Xe arc lamp equipped with a 435 nm long-pass filter was used to irradiate the sample for 30 min at room temperature at a distance of 10 cm. Lastly, a confocal fluorescence microscope with 561 nm excitation was used to visualize the results of photocatalytic dye degradation. Tiling experiments were performed with a focus strategy using support points and subsequently stitched together. Image processing and analysis was performed in Zen 3.0 (Carl Zeiss) or Fiji/ImageJ (National Institutes of Health).

The foregoing description is given for clearness of understanding only, and no unnecessary limitations should be understood therefrom, as modifications within the scope of the disclosure may be apparent to those having ordinary skill in the art.

All patents, patent applications, government publications, government regulations, and literature references cited in this specification are hereby incorporated herein by reference in their entirety. In the case of conflict, the present description, including definitions, will control.

Throughout the specification, where the compounds, compositions, methods, and/or processes are described as including components, steps, or materials, it is contemplated that the compounds, compositions, methods, and/or processes can also comprise, consist essentially of, or consist of any combination of the recited components or materials, unless described otherwise. Component concentrations can be expressed in terms of weight concentrations, unless specifically indicated otherwise. Combinations of components are contemplated to include homogeneous and/or heterogeneous mixtures, as would be understood by a person of ordinary skill in the art in view of the foregoing disclosure.

### REFERENCES

(1) Haber, J. A.; Cai, Y.; Jung, S.; Xiang, C.; Mitrovic, S.; Jin, J.; Bell, A. T.; Gregoire, J. M. Discovering Ce-rich oxygen evolution catalysts, from high throughput screening to water electrolysis. Energy Environ. Sci. 2014, 7, 682-688.
(2) Kluender, E. J.; Hedrick, J. L.; Brown, K. A.; Rao, R.; Meckes, B.; Du, J. S.; Moreau, L. M.; Maruyama, B.; Mirkin, C. A. Catalyst discovery through megalibraries of nanomaterials. Proc. Natl. Acad. Sci. U.S.A. 2019, 116, 40-45.
(3) Hitt, J. L.; Li, Y. C.; Tao, S.; Yan, Z.; Gao, Y.; Billinge, S. J. L.; Mallouk, T. E. A high throughput optical method for studying compositional effects in electrocatalysts for CO₂ reduction. Nat. Commun. 2021, 12, 1114.
(4) Wang, J.; Yoo, Y.; Gao, C.; Takeuchi, I. I.; Sun, X.; Chang, H.; Xiang, X.; Schultz, P. G. Identification of a blue photoluminescent composite material from a combinatorial library. Science 1998, 279, 1712-1714.
(5) Lai, M.; Shin, D.; Jibril, L.; Mirkin, C. A. Combinatorial Synthesis and Screening of Mixed Halide Perovskite Megalibraries. J. Am. Chem. Soc. 2022, 144, 13823-13830.
(6) Alstrup, J.; Jorgensen, M.; Medford, A. J.; Krebs, F. C. Ultra fast and parsimonious materials screening for polymer solar cells using differentially pumped slot-die coating. ACS Appl. Mater. Interfaces 2010, 2, 2819-2827.
(7) Moradi, S.; Kundu, S.; Saidaminov, M. I. High-Throughput Synthesis of Thin Films for the Discovery of Energy Materials: A Perspective. ACS Mater Au 2022, 2, 516-524.
(8) Chazalviel, J. N.; Allongue, P. On the origin of the efficient nanoparticle mediated electron transfer across a self-assembled monolayer. J. Am. Chem. Soc. 2011, 133, 762-764.
(9) Knight, M. W.; Wu, Y.; Lassiter, J. B.; Nordlander, P.; Halas, N. J. Substrates matter: influence of an adjacent dielectric on an individual plasmonic nanoparticle. Nano Lett. 2009, 9, 2188-2192.
(10) Wu, P.; Tan, S.; Moon, J.; Yan, Z.; Fung, V.; Li, N.; Yang, S. Z.; Cheng, Y.; Abney, C. W.; Wu, Z.; Savara, A.; Momen, A. M.; Jiang, D. E.; Su, D.; Li, H.; Zhu, W.; Dai, S.; Zhu, H. Harnessing strong metal-support interactions via a reverse route. Nat. Commun. 2020, 11, 3042.
(11) Hvolbæk, B.; Janssens, T. V. W.; Clausen, B. S.; Falsig, H.; Christensen, C. H.; Nørskov, J. K. Catalytic activity of Au nanoparticles. Nano Today 2007, 2, 14-18.
(12) Cuenya, B. R. Synthesis and catalytic properties of metal nanoparticles: Size, shape, support, composition, and oxidation state effects. Thin Solid Films 2010, 518, 3127-3150.
(13) Crawley, J. W. M.; Gow, I. E.; Lawes, N.; Kowalec, I.; Kabalan, L.; Catlow, C. R. A.; Logsdail, A. J.; Taylor, S. H.; Dummer, N. F.; Hutchings, G. J. Heterogeneous Trimetallic Nanoparticles as Catalysts. Chem. Rev. 2022, 122, 6795-6849.
(14) Haynes, C. L.; Van Duyne, R. P. Nanosphere Lithography: A Versatile Nanofabrication Tool for Studies of Size-Dependent Nanoparticle Optics. J. Phys. Chem. B 2001, 105, 5599-5611.
(15) Liu, X.; Fu, L.; Hong, S.; Dravid, V. P.; Mirkin, C. A. Arrays of Magnetic Nanoparticles Patterned via “Dip-Pen” Nanolithography. Adv. Mater. 2002, 14, 231-234.
(16) Neretina, S.; Hughes, R. A.; Gilroy, K. D.; Hajfathalian, M. Noble Metal Nanostructure Synthesis at the Liquid-Substrate Interface: New Structures, New Insights, and New Possibilities. Acc. Chem. Res. 2016, 49, 2243-2250.
(17) Barad, H. N.; Kwon, H.; Alarcon-Correa, M.; Fischer, P. Large Area Patterning of Nanoparticles and Nanostructures: Current Status and Future Prospects. ACS Nano 2021, 15, 5861-5875.
(18) Spatz, J. P.; Mössmer, S.; Hartmann, C.; Möller, M.; Herzog, T.; Krieger, M.; Boyen, H.-G.; Ziemann, P.; Kabius, B. Ordered Deposition of Inorganic Clusters from Micellar Block Copolymer Films. Langmuir 1999, 16, 407-415.
(19) Shevchenko, E. V.; Talapin, D. V.; Rogach, A. L.; Kornowski, A.; Haase, M.; Weller, H. Colloidal synthesis and self-assembly of CoPt₃ nanocrystals. J. Am. Chem. Soc. 2002, 124, 11480-11485.
(20) Qn, D.; Xia, Y.; Xu, B.; Yang, H.; Zhu, C.; Whitesides, G. M. Fabrication of Ordered Two-Dimensional Arrays of Micro- and Nanoparticles Using Patterned Self-Assembled Monolayers as Templates. Adv. Mater. 1999, 11, 1433-1437.
(21) Zhou, W.; Liu, Z.; Huang, Z.; Lin, H.; Samanta, D.; Lin, Q. Y.; Aydin, K.; Mirkin, C. A. Device-quality, reconfigurable metamaterials from shape-directed nanocrystal assembly. Proc. Natl. Acad. Sci. U.S.A. 2020, 117, 21052-21057.
(22) Hughes, R. A.; Menumerov, E.; Neretina, S. When lithography meets self-assembly: a review of recent advances in the directed assembly of complex metal nanostructures on planar and textured surfaces. Nanotechnology 2017, 28, 282002.
(23) Chai, J.; Huo, F.; Zheng, Z.; Giam, L. R.; Shim, W.; Mirkin, C. A. Scanning probe block copolymer lithography. Proc. Natl. Acad. Sci. U.S.A. 2010, 107, 20202-20206.
(24) Chen, P. C.; Liu, G.; Zhou, Y.; Brown, K. A.; Chernyak, N.; Hedrick, J. L.; He, S.; Xie, Z.; Lin, Q. Y.; Dravid, V. P.; O'Neill-Slawecki, S. A.; Mirkin, C. A. Tip-Directed Synthesis of Multimetallic Nanoparticles. J. Am. Chem. Soc. 2015, 137, 9167-9173.
(25) Chen, P. C.; Liu, X.; Hedrick, J. L.; Xie, Z.; Wang, S.; Lin, Q. Y.; Hersam, M. C.; Dravid, V. P.; Mirkin, C. A. Polyelemental nanoparticle libraries. Science 2016, 352, 1565-1569.
(26) Wahl, C. B.; Aykol, M.; Swisher, J. H.; Montoya, J. H.; Suram, S. K.; Mirkin, C. A. Machine learning-accelerated design and synthesis of polyelemental heterostructures. Sci. Adv. 2021, 7, eabj5505.
(27) Huo, F.; Zheng, Z.; Zheng, G.; Giam, L. R.; Zhang, H.; Mirkin, C. A. Polymer pen lithography. Science 2008, 321, 1658-1660.
(28) Liu, G.; Eichelsdoerfer, D. J.; Rasin, B.; Zhou, Y.; Brown, K. A.; Liao, X.; Mirkin, C. A. Delineating the pathways for the site-directed synthesis of individual nanoparticles on surfaces. Proc. Natl. Acad. Sci. U.S.A. 2013, 110, 887-891.
(29) Xu, D. D.; Wahl, C. B.; Du, J. S.; Irgen-Gioro, S.; Weiss, E. A.; Mirkin, C. A. Site-Isolated Upconversion Nanoparticle Arrays Synthesized in Polyol Nanoreactors. J. Phys. Chem. C 2021, 125, 26125-26131.
(30) Du, J. S.; Shin, D.; Stanev, T. K.; Musumeci, C.; Xie, Z.; Huang, Z.; Lai, M.; Sun, L.; Zhou, W.; Stern, N. P.; Dravid, V. P.; Mirkin, C. A. Halide perovskite nanocrystal arrays: Multiplexed synthesis and size-dependent emission. Sci. Adv. 2020, 6, eabc4959.
(31) Hedrick, J. L.; Brown, K. A.; Kluender, E. J.; Cabezas, M. D.; Chen, P. C.; Mirkin, C. A. Hard Transparent Arrays for Polymer Pen Lithography. ACS Nano 2016, 10, 3144-3148.
(32) Ding, M.; Tang, Y.; Star, A. Understanding Interfaces in Metal-Graphitic Hybrid Nanostructures. J Phys Chem Lett 2013, 4, 147-160.
(33) Gawande, M. B.; Fornasiero, P.; Zbořil, R. Carbon-Based Single-Atom Catalysts for Advanced Applications. ACS Catal. 2020, 10, 2231-2259.
(34) Ranganathan, S.; McCreery, R. L. Electroanalytical performance of carbon films with near-atomic flatness. Anal. Chem. 2001, 73, 893-900.
(35) Huang, Z.; Yao, Y.; Pang, Z.; Yuan, Y.; Li, T.; He, K.; Hu, X.; Cheng, J.; Yao, W.; Liu, Y.; Nie, A.; Sharifi-Asl, S.; Cheng, M.; Song, B.; Amine, K.; Lu, J.; Li, T.; Hu, L.; Shahbazian-Yassar, R. Direct observation of the formation and stabilization of metallic nanoparticles on carbon supports. Nat. Commun. 2020, 11, 6373.
(36) Pujari, S. P.; Scheres, L.; Marcelis, A. T.; Zuilhof, H. Covalent surface modification of oxide surfaces. Angew. Chem. Int. Ed. 2014, 53, 6322-6356.
(37) Blanchard, L.-P.; Hesse, J.; Malhotra, S. L. Effect of Molecular Weight on Glass Transition by Differential Scanning calorimetry. Can. J. Chem. 1974, 52, 3170-3175.
(38) McCreery, R. L. Advanced carbon electrode materials for molecular electrochemistry. Chem. Rev. 2008, 108, 2646-2687.
(39) Pijpers, J. J.; Winkler, M. T.; Surendranath, Y.; Buonassisi, T.; Nocera, D. G. Light-induced water oxidation at silicon electrodes functionalized with a cobalt oxygen-evolving catalyst. Proc. Natl. Acad. Sci. U.S.A. 2011, 108, 10056-10061.
(40) Liu, Q.; Chen, C.; Du, M.; Wu, Y.; Ren, C.; Ding, K.; Song, M.; Huang, C. Porous Hexagonal Boron Nitride Sheets: Effect of Hydroxyl and Secondary Amino Groups on Photocatalytic Hydrogen Evolution. ACS Appl. Nano Mater. 2018, 1, 4566-4575.
(41) Antolini, E.; Gonzalez, E. R. Tungsten-based materials for fuel cell applications. Appl. Catal. B Environ. 2010, 96, 245-266.
(42) Zhuang, H.; Yang, N.; Zhang, L.; Fuchs, R.; Jiang, X. Electrochemical properties and applications of nanocrystalline, microcrystalline, and epitaxial cubic silicon carbide films. ACS Appl. Mater. Interfaces 2015, 7, 10886-10895.
(43) Tran, T. T.; Bray, K.; Ford, M. J.; Toth, M.; Aharonovich, I. Quantum emission from hexagonal boron nitride monolayers. Nat. Nanotechnol. 2016, 11, 37-41.
(44) Yin, L.; Cheng, H.; Mao, S.; Haasch, R.; Liu, Y.; Xie, X.; Hwang, S. W.; Jain, H.; Kang, S. K.; Su, Y.; Li, R.; Huang, Y.; Rogers, J. A. Dissolvable Metals for Transient Electronics. Adv. Funct. Mater. 2013, 24, 645-658.
(45) Nistor, P. A.; May, P. W. Diamond thin films: giving biomedical applications a new shine. J R Soc Interface 2017, 14, 20170382.
(46) Torbensen, K.; Iruthayaraj, J.; Ceccato, M.; Kongsfelt, M.; Breitenbach, T.; Pedersen, S. U.; Daasbjerg, K. Conducting and ordered carbon films obtained by pyrolysis of covalently attached polyphenylene and polyanthracene layers on silicon substrates. J. Mater. Chem. 2012, 22, 18172-18180.
(47) Stavis, C.; Clare, T. L.; Butler, J. E.; Radadia, A. D.; Carr, R.; Zeng, H.; King, W. P.; Carlisle, J. A.; Aksimentiev, A.; Bashir, R.; Hamers, R. J. Surface functionalization of thin-film diamond for highly stable and selective biological interfaces. Proc. Natl. Acad. Sci. U.S.A. 2011, 108, 983-988.
(48) Ren, J.; Stagi, L.; Innocenzi, P. Hydroxylated boron nitride materials: from structures to functional applications. J. Mater. Sci. 2020, 56, 4053-4079.
(49) Alekseev, S.; Shamatulskaya, E.; Volvach, M.; Gryn, S.; Korytko, D.; Bezverkhyy, I.; lablokov, V.; Lysenko, V. Size and Surface Chemistry Tuning of Silicon Carbide Nanoparticles. Langmuir 2017, 33, 13561-13571.
(50) Juma, A. O.; Acik, I. O.; Mikli, V.; Mere, A.; Krunks, M. Effect of solution composition on anatase to rutile transformation of sprayed TiO₂ thin films. Thin Solid Films 2015, 594, 287-292.
(51) Wang, P.; Shao, Z.; Ulfa, M.; Pauporté, T. Insights into the Hole Blocking Layer Effect on the Perovskite Solar Cell Performance and Impedance Response. J. Phys. Chem. C 2017, 121, 9131-9141.
(52) Fujishima, A.; Zhang, X.; Tryk, D. TiO₂ photocatalysis and related surface phenomena. Surf. Sci. Rep. 2008, 63, 515-582.
(53) Liu, X.; Zhu, G.; Wang, X.; Yuan, X.; Lin, T.; Huang, F. Progress in Black Titania: A New Material for Advanced Photocatalysis. Adv. Energy Mater. 2016, 6, 1600452.
(54) Liao, X.; Braunschweig, A. B.; Zheng, Z.; Mirkin, C. A. Force- and time-dependent feature size and shape control in molecular printing via polymer-pen lithography. Small 2010, 6, 1082-1086.
(55) Danielson, E.; Golden, J. H.; McFarland, E. W.; Reaves, C. M.; Weinberg, W. H.; Wu, X. D. A combinatorial approach to the discovery and optimization of luminescent materials. Nature 1997, 389, 944-948.
(56) McGinn, P. J. Thin-Film Processing Routes for Combinatorial Materials Investigations-A Review. ACS Comb. Sci. 2019, 21, 501-515.
(57) Yang, L.; Haber, J. A.; Armstrong, Z.; Yang, S. J.; Kan, K.; Zhou, L.; Richter, M. H.; Roat, C.; Wagner, N.; Coram, M.; Berndl, M.; Riley, P.; Gregoire, J. M. Discovery of complex oxides via automated experiments and data science. Proc. Natl. Acad. Sci. U.S.A. 2021, 118.
(58) Prieto, G.; Zecevic, J.; Friedrich, H.; de Jong, K. P.; de Jongh, P. E. Towards stable catalysts by controlling collective properties of supported metal nanoparticles. Nat. Mater. 2013, 12, 34-39.
(59) Manthiram, K.; Surendranath, Y.; Alivisatos, A. P. Dendritic assembly of gold nanoparticles during fuel-forming electrocatalysis. J. Am. Chem. Soc. 2014, 136, 7237-7240.
(60) Goodman, E. D.; Johnston-Peck, A. C.; Dietze, E. M.; Wrasman, C. J.; Hoffman, A. S.; Abild-Pedersen, F.; Bare, S. R.; Plessow, P. N.; Cargnello, M. Supported Catalyst Deactivation by Decomposition into Single Atoms Is Suppressed by Increasing Metal Loading. Nat. Catal. 2019, 2, 748-755.
(61) Primo, A.; Corma, A.; Garcia, H. Titania supported gold nanoparticles as photocatalyst. Phys. Chem. Chem. Phys. 2011, 13, 886-910.
(62) Ajmal, A.; Majeed, I.; Malik, R. N.; Idriss, H.; Nadeem, M. A. Principles and mechanisms of photocatalytic dye degradation on TiO₂ based photocatalysts: a comparative overview. RSC Adv. 2014, 4, 37003-37026.
(63) Aarthi, T.; Madras, G. Photocatalytic Degradation of Rhodamine Dyes with Nano-TiO₂. Ind. Eng. Chem. Res. 2006, 46, 7-14.
(64) Bian, Z.; Tachikawa, T.; Zhang, P.; Fujitsuka, M.; Majima, T. Au/TiO₂ superstructure-based plasmonic photocatalysts exhibiting efficient charge separation and unprecedented activity. J. Am. Chem. Soc. 2014, 136, 458-465.
(65) Lee, S. Y.; Kang, D.; Jeong, S.; Do, H. T.; Kim, J. H. Photocatalytic Degradation of Rhodamine B Dye by TiO₂ and Gold Nanoparticles Supported on a Floating Porous Polydimethylsiloxane Sponge under Ultraviolet and Visible Light Irradiation. ACS Omega 2020, 5, 4233-4241.
(66) Veziroglu, S.; Obermann, A. L.; Ullrich, M.; Hussain, M.; Kamp, M.; Kienle, L.; Leissner, T.; Rubahn, H. G.; Polonskyi, O.; Strunskus, T.; Fiutowski, J.; Es-Souni, M.; Adam, J.; Faupel, F.; Aktas, O. C. Photodeposition of Au Nanoclusters for Enhanced Photocatalytic Dye Degradation over TiO₂ Thin Film. ACS Appl. Mater. Interfaces 2020, 12, 14983-14992.
(67) Rafiq, A.; Ikram, M.; Ali, S.; Niaz, F.; Khan, M.; Khan, Q.; Maqbool, M. Photocatalytic degradation of dyes using semiconductor photocatalysts to clean industrial water pollution. J. Ind. Eng. Chem. 2021, 97, 111-128.
(68) Clavero, C. Plasmon-induced hot-electron generation at nanoparticle/metal-oxide interfaces for photovoltaic and photocatalytic devices. Nat. Photonics 2014, 8, 95-103.
(69) Li, Z.; Meng, X. Recent development on palladium enhanced photocatalytic activity: A review. J. Alloys Compd. 2020, 830, 154669.
(70) Xin, Y.; Yu, K.; Zhang, L.; Yang, Y.; Yuan, H.; Li, H.; Wang, L.; Zeng, J. Copper-Based Plasmonic Catalysis: Recent Advances and Future Perspectives. Adv. Mater. 2021, 33, e2008145.
(71) Meng, A.; Zhang, L.; Cheng, B.; Yu, J. Dual Cocatalysts in TiO₂ Photocatalysis. Adv. Mater. 2019, 31, e1807660.
(72) Padre, S. M.; Kiruthika, S.; Mundinamani, S.; Ravikirana; Surabhi, S.; Jeong, J. R.; Eshwarappa, K. M.; Murari, M. S.; Shetty, V.; Ballal, M.; S, C. G. Mono- and Bimetallic Nanoparticles for Catalytic Degradation of Hazardous Organic Dyes and Antibacterial Applications. ACS Omega 2022, 7, 35023-35034.
(73) Misra, M.; Singh, N.; Gupta, R. K. Enhanced visible-light-driven photocatalytic activity of Au@Ag core-shell bimetallic nanoparticles immobilized on electrospun TiO₂ nanofibers for degradation of organic compounds. Catal. Sci. Technol. 2017, 7, 570-580.
(74) Sahoo, A.; Tripathy, S. K.; Dehury, N.; Patra, S. A porous trimetallic Au@Pd@Ru nanoparticle system: synthesis, characterisation and efficient dye degradation and removal. J. Mater. Chem. A 2015, 3, 19376-19383.
(75) Bruemmer, K. J.; Crossley, S. W. M.; Chang, C. J. Activity-Based Sensing: A Synthetic Methods Approach for Selective Molecular Imaging and Beyond. Angew. Chem. Int. Ed. 2020, 59, 13734-13762.
(1) Eichelsdoerfer, D. J.; Liao, X.; Cabezas, M. D.; Morris, W.; Radha, B.; Brown, K. A.; Giam, L. R.; Braunschweig, A. B.; Mirkin, C. A. Large-area molecular patterning with polymer pen lithography. Nat. Protoc. 2013, 8, 2548-2560.
(2) Wahl, C. B.; Aykol, M.; Swisher, J. H.; Montoya, J. H.; Suram, S. K.; Mirkin, C. A. Machine learning-accelerated design and synthesis of polyelemental heterostructures. Sci. Adv. 2021, 7, eabj5505.
(3) Juma, A. O.; Acik, I. O.; Mikli, V.; Mere, A.; Krunks, M. Effect of solution composition on anatase to rutile transformation of sprayed TiO₂ thin films. Thin Solid Films 2015, 594, 287-292.
(4) Wang, P.; Shao, Z.; Ulfa, M.; Pauporte, T. Insights into the Hole Blocking Layer Effect on the Perovskite Solar Cell Performance and Impedance Response. J. Phys. Chem. C 2017, 121, 9131-9141.
(5) Zhao, L. Y.; Jalili, H.; Panjwani, N.; Chan, T.; He, Z. H.; Heinig, N. F.; Leung, K. T. Formation of Ferromagnetic Iron Core-Shell Nanocubes on a H-Terminated Si (100) Surface by Electrodeposition. Electrochem. Solid-State Lett. 2007, 10, K47.
US20110165341A1
US20150210868A1
US20210163707A1
Disc-ID-21-09-30-001
Chai, J.; Huo, F.; Zheng, Z.; Giam, L. R.; Shim, W.; Mirkin, C. A., Scanning probe block copolymer lithography. Proc. Natl. Acad. Sci. U.S.A. 2010, 107 (47), 20202-6.
Kluender, E. J.; Hedrick, J. L.; Brown, K. A.; Rao, R.; Meckes, B.; Du, J. S.; Moreau, L. M.; Maruyama, B.; Mirkin, C. A., Catalyst discovery through megalibraries of nanomaterials. Proc. Natl. Acad. Sci. U.S.A. 2019, 116 (1), 40-45.
Huang, L., Chen, P. C.; Liu, M.; Fu, X.; Gordiichuk, P.; Yu, Y.; Wolverton, C.; Kang, Y.; Mirkin, C. A. Catalyst design by scanning probe block copolymer lithography. Proc. Natl. Acad. Sci. U.S.A. 2018, 115, 3764-3769.
Liu, Y.; Kong, L.; Wu, R.; Chen, Y.; Huangfu, Y.; Liu, L.; Li, W.; Lu, D.; Tao, Q.; Song, W.; Li, W.; Lu, Z.; Liu, X.; Li, Z.; Tong, W.; Ding, S.; Liu, S.; Ma, L.; Ren, L; Wang, Y; Liao, L. Wafer-scale and universal van der Waals metal semiconductor contact. Research Square 2022, 10.21203/rs.21203.rs-1591719/1591711.

1. A method of forming nanoparticles on a substrate, comprising:
coating a substrate with a substrate coating, wherein the substrate coating is a flat, hydrophobic coating;
depositing a precursor ink comprising a polymer and one or more metal ions and/or one or more metal ion precursors onto the substrate coating to form a plurality of polymer nanoreactors comprising the one or more metal ions and/or one or more metal ion precursors contained within the polymer nanoreactor;
annealing the substrate having the polymer nanoreactors formed on the substrate coating to aggregate the one or more metal ions and/or one or more metal ions from the one or more metal ion precursor and form nanoparticles within the polymer nanoreactors; and
removing the substrate coating thereby resulting in the nanoparticles formed on the substrate.

2. The method of claim 1, wherein the substrate coating is a fluorinated or non-fluorinated hydrophobic polymers that decompose with applied heat.

3. The method of claim 1, wherein the substrate coating is polystyrene, polyethylene, Poly(α-methyl styrene), Poly(2,6-dimethyl-1,4-phenylene oxide), polyolefins, polydienes, poly(pentafluorostyrene), poly(tetrafluoroethylene), or poly(vinylidene fluoride).

4. The method of claim 1, wherein the substrate coating is a molecular coating of one or more of rubrene pyrene, terphenyl, triptycene, hexaphenylbenzene, or coroners.

5. The method of claim 1, wherein the substrate coating has a thickness of about 100 nm to about 500 nm.

6. The method of claim 1, wherein the substrate coating has a water contact angle of greater than 75°.

7. The method of claim 1, wherein the substrate coating decomposes at a temperature 100° C. to 600° C.

8. The method of claim 1, wherein coating the substrate with the substrate coating comprises spin coating, dip coating, drop casting, vapor deposition, or spray coating the substrate coating onto the substrate.

9. The method of claim 1, wherein the substrate coating has a surface roughness of less than 1 nm.

10. The method of claim 1, wherein annealing comprises heating the substrate having the polymer nanoreactors to a temperature of about 100° C. to about 250° C.

11. The method of claim 1, wherein depositing the precursor ink comprises patterning the precursor ink using pen array.

12. The method of claim 1, wherein the precursor ink is deposited by polymer pen lithography.

13. The method of claim 1, wherein the precursor ink is deposited using scanning probe block copolymer lithography.

14. The method of claim 1, wherein the polymer is a block copolymer.

15. The method of claim 14, wherein the block copolymer is PEO-b-PVP.

16. The method of claim 1, wherein the polymer is a non-block copolymer.

17. The method of claim 1, wherein the substrate has a surface height variation of greater than 5 nm.

18. The method of claim 1, wherein the substrate comprises glassy carbon, pyrolyzed photoresist, graphene, HOPG, diamond, boron nitride, silicon carbide, tungsten, molybdenum, titanium, and/or titania.
